(19) United States
(12) Patent Application Publication
(10) Pub. No.: US 2026/0302148 A1
(43) Pub. Date: Oct. 1, 2026

(54) PLASMA PROCESSING APPARATUS

(71) Applicant: ULVAC, Inc., Chigasaki-shi, Kanagawa (JP)

(72) Inventors: Tetsushi FUJINAGA, Chigasaki-shi (JP); Hantaro OZAWA, Chigasaki-shi (JP)

(73) Assignee: ULVAC, Inc., Chigasaki-shi, Kanagawa (JP)

(21) Appl. No.: 19/480,351

(22) PCT Filed: Sep. 20, 2024
(86) PCT No.: PCT/JP2024/033682

§ 371 Date: Oct. 30, 2025

(30) Foreign Application Priority Data
Oct. 12, 2023 (JP) 2023-176528

(51) Int. Cl. H01J 37/34; C23C 14/35; H01J 37/32

(52) U.S. Cl. CPC H01J 37/3452; C23C 14/35; H01J 37/3244; H01J 2237/002; H01J 2237/332

(57) ABSTRACT

A plasma processing apparatus includes a vacuum chamber, a sputtering cathode including a target and a plurality of magnet units, a substrate support part, a plasma generation power supply, a gas-atmosphere setting part, and a magnetic-field generation power supply. The plurality of magnet units are disposed to generate a leakage magnetic field obtained by superimposing a plurality of magnetic fields generated by the plurality of magnet units in a film formation space facing the sputtering surface of the target. The plurality of magnet units are configured to change the leakage magnetic field in a direction parallel to a center axis passing through a center of the sputtering surface and extending in a thickness direction of the target, a radial direction with respect to the center of the sputtering surface, and a circumferential direction of the sputtering surface around the center axis.

### TECHNICAL FIELD

The present invention relates to a plasma processing apparatus.

Priority is claimed on Japanese Patent Application No. 2023-176528, filed Oct. 12, 2023, the content of which is incorporated herein by reference.

### BACKGROUND ART

A film forming process step is known as one process step in a semiconductor manufacturing process or a flat panel display manufacturing process. In the film forming process step, a predetermined thin film is formed on the surface of a to-be-processed substrate such as a rectangular glass substrate or a circular silicon wafer. In this film forming process step, a magnetron sputtering apparatus is widely used. The sputtering apparatus includes a vacuum chamber and a cathode unit that is disposed to face a to-be-processed substrate that is to be set in the vacuum chamber.

The cathode unit includes a target and a magnet unit. The target has a shape corresponding to a substrate (a to-be-processed substrate) and has a larger area than the substrate. The target includes a sputtering surface serving as a surface to be subjected to sputtering. The magnet unit is disposed on the side opposite to the sputtering surface of the target. The magnet unit applies a leakage magnetic field to a space facing the sputtering surface.

In the magnetron sputtering apparatus, while sputtering is being performed, the magnet unit is caused to reciprocate at a predetermined speed in an orthogonal direction or the magnet unit is caused to rotate at a predetermined speed in a circumferential direction.

In Patent Document 1, a configuration is described in which a moving magnetic field is generated by controlling a current supply state in a plurality of electromagnets arranged in the cathode unit without moving a magnet in the cathode unit of the magnetron sputtering apparatus.

### CITATION LIST

### Patent Document

Patent Document 1: Japanese Unexamined Patent Application, First Publication No. 2020-139213

### SUMMARY OF INVENTION

### Technical Problem

However, in the technique disclosed in Patent Document 1, control of a magnetic field to be generated, control of a plasma distribution, and countermeasures against a non-erosion area formed in a target are not satisfactory. This reason is as follows.

In film formation using sputtering, sputtering particles discharged from a target exhibit various behaviors according to types or elements of metal constituting the target. When sputtering conditions change, flying courses of sputtering particles from the target to a substrate change complicatedly. In order to obtain a desired film formation distribution using sputtering, adjustment of a magnetic circuit constituted by a plurality of magnets, adjustment of a pressure in a film formation space in the vacuum chamber, adjustment of a T/S distance (a distance between a target and a substrate), adjustment of a T/M distance (a distance between a target and a magnet), adjustment of a bias voltage to a substrate, adjustment of an external magnetic field, and the like are performed.

Recently, a distribution excellent in uniformity such as less than ±5% has come to be required as a film formation distribution obtained using the magnetron sputtering apparatus. However, very minute adjustment is required to obtain a distribution excellent in uniformity through the aforementioned various types of adjustment in a conventional sputtering cathode. Accordingly, there is a problem in that much labor and time is required to adjust to a distribution excellent in uniformity and thus facilitation of the aforementioned adjustment cannot be realized.

With a history of successive film formation on a plurality of substrates, a shape of a film formation distribution excellent in uniformity using sputtering collapses easily. The reason is that an inevitable change over time such as a change in shape of a target with sputtering and attachment of a film to a shield member exposed to the inside of the film formation space affects a shape of a film formation distribution. Accordingly, there is also a problem in that it is difficult to obtain reproducibility of the film formation distribution.

In this regard, it is conceivable that it be tried to adjust the film formation distribution by controlling currents supplied to a plurality of electromagnets. However, in this case, for example, it is necessary to obtain a state of magnetic fields generated by a plurality of electromagnets, a magnetic field spatial distribution obtained by superimposing a plurality of magnetic fields generated by a plurality of electromagnets in a film formation space corresponding to the whole substrate, a change over time of a magnetic field spatial distribution, a plasma three-dimensional distribution changing according to a magnetic field, and a non-erosion area state. It is necessary to set control currents for controlling a plurality of electromagnets from the obtained information in consideration of an actual film formation state (a film formation profile). Accordingly, when determining setting conditions such as currents required to realize a desired film formation state, a non-realistically large amount of work time and number of work steps are required.

A configuration of a power supply capable of accurately supplying desired control currents to a plurality of electromagnets also is not known.

The invention was made in consideration of the aforementioned circumstances and for the purpose of achieving the following objectives.
1. To provide an apparatus capable of controlling a magnetic field required to perform a desired process in a plasma process such as a film forming process of changing magnetic fields generated by a plurality of magnets.
2. To provide an apparatus capable of easily setting currents for controlling a necessary magnetic field and shorten a calculation time required for setting the currents.
3. To provide an apparatus capable of increasing a control margin for controlling a magnetic field required to perform a desired process in a plasma process such as a film forming process of changing magnetic fields generated by a plurality of magnets.

### Solution to Problem

In order to achieve the aforementioned objectives, a plasma processing apparatus according to an aspect of the invention includes a vacuum chamber having a film formation space, a sputtering cathode including a target disposed in the vacuum chamber and having a sputtering surface and a plurality of magnet units located on a side of the target opposite to the sputtering surface, a substrate support part disposed to face the target in the vacuum chamber and configured to support a substrate, a plasma generation power supply configured to supply electric power to the sputtering cathode and to generate plasma in the vacuum chamber, a gas-atmosphere setting part configured to set a gas atmosphere in the film formation space by supplying gas into the vacuum chamber and discharging the gas from the vacuum chamber, and a magnetic-field generation power supply configured to supply electric power to the plurality of magnet units and to generate a magnetic field in each of the plurality of magnet units. The plurality of magnet units are disposed in the film formation space facing the sputtering surface so as to generate a leakage magnetic field obtained by superimposing a plurality of magnetic fields generated by the plurality of magnet units. The plurality of magnet units are configured to change the leakage magnetic field in a direction parallel to a center axis passing through a center of the sputtering surface and extending in a thickness direction of the target, a radial direction with respect to the center of the sputtering surface, and a circumferential direction of the sputtering surface around the center axis.

With this configuration, since the magnetic-field generation power supply supplies electric power to the plurality of magnet units, each of the plurality of magnet units generates a magnetic field. A leakage magnetic field generated by superimposing a plurality of magnetic fields generated by the plurality of magnet units is generated in the film formation space facing the sputtering surface. The leakage magnetic field changes in the direction parallel to the center axis, the radial direction, and the circumferential direction. Regarding the leakage magnetic field, the plurality of magnet units can generate a rotating magnetic field rotating with respect to the target and generate an oscillating magnetic field oscillating with respect to the target. It is possible to increase a control margin for controlling a magnetic field required to obtain a desired plasma state.

With this configuration, it is possible to control the magnetic fields generated by the plurality of magnet units. Accordingly, it is possible to superimpose desired magnetic fields with a specific distribution and a specific shape, to minutely control the magnetic fields, and to control a change over time of the magnetic fields. Particularly, it is possible to supply currents to the magnet units in a state in which a specific current waveform of the currents supplied to the plurality of magnet units has been precisely controlled. Accordingly, it is not necessary to perform attachment and detachment of the magnet units or the like for the purpose of control of the magnetic fields, and it is possible to decrease an amount of operation and an operation time for obtaining a desired magnetic field.

Accordingly, it is possible to easily perform a desired plasma process with a higher degree of precision by generating plasma having a specific spatial distribution. As a result, it is possible to achieve improvement in processing characteristics such as a film thickness distribution and film characteristics.

With this apparatus, the gas-atmosphere setting part sets the gas atmosphere in the vacuum chamber, the substrate support part supports a substrate in the vacuum chamber, and electric power is supplied to the sputtering cathode from the plasma generation power supply. Accordingly, plasma is generated in the film formation space, and a plasma process is performed on the substrate. An erosion area is formed in the target opposite to the substrate. In this generation of plasma, the magnetic-field generation power supply supplies electric power to the plurality of magnet units, and the plurality of magnet units generate a magnetic field. A magnetic field required for each of the plurality of magnet units is applied to plasma, and a plasma process such as sputtering is performed. Accordingly, it is possible to form a film having a desired profile on a substrate and to obtain excellent processing characteristics.

Conventionally, much labor and time are caused in an operation of setting film formation conditions optimal for obtaining a desired film formation distribution, a maintenance operation for the plasma processing apparatus, or an operation of assembling a magnetic circuit. On the other hand, in the plasma processing apparatus according to the aspect of the invention, it is possible to avoid occurrence of much labor and time and to easily adjust processing characteristics such as a film formation distribution. Even when the processing characteristics change with a change over time due to consecutive processes such as consecutive film formation on the substrate, it is possible to easily correct a distribution of processing characteristics. As a result, it is possible to improve productivity of the plasma processing apparatus.

In the plasma processing apparatus according to the aspect of the invention, each of the plurality of magnet units may be disposed to generate the magnetic field in the direction parallel to the center axis. Two magnet units adjacent to each other out of the plurality of magnet units may be disposed to be separated in the radial direction.

With this configuration, it is possible to easily generate a desired magnetic field with a high degree of precision between a target and a substrate. It is possible to form a closed magnetic circuit using two magnet units adjacent to each other which are separated in the radial direction, to generate plasma with a predetermined shape using a magnetic field generated by the magnetic circuit, and to perform a plasma process.

In the plasma processing apparatus according to the aspect of the invention, two magnet units adjacent to each other out of the plurality of magnet units may be disposed to be separated in the circumferential direction.

With this configuration, it is possible to form a closed magnetic circuit using two magnet units adjacent to each other which are separated in the circumferential direction, to generate plasma with a predetermined shape using a magnetic field generated by the magnetic circuit, and to perform a plasma process. It is possible to supply AC power of different phases to the plurality of magnet units which are arranged in the radial direction and separated in the circumferential direction. In this case, it is possible to generate magnetic fields in a plurality of phases using the plurality of magnet units and to superimpose the magnetic fields. Accordingly, it is possible to easily generate a magnetic field rotating around the center axis.

In the plasma processing apparatus according to the aspect of the invention, each of the plurality of magnet units may have a configuration of one of: a permanent magnet; an electromagnet; a combination of a plurality of permanent magnets; a combination of a plurality of electromagnets; and a combination of a permanent magnet and an electromagnet.

With this configuration, it is possible to finely set and dispose magnetic fields generated by the plurality of magnet units which are located at different positions in the radial direction or the circumferential direction. Accordingly, it is possible to control a generated magnetic field with a higher degree of precision than that in the conventional one. As a result, it is possible to fix the generated magnetic field, to change a phase according to a change over time, or to increase a control width of the magnetic field, for example, using the plurality of magnet units which are arranged in the radial direction and separated in the circumferential direction.

In the plasma processing apparatus according to the aspect of the invention, at least one of the plurality of magnet units may include a plurality of magnets. The plurality of magnets may generate the magnetic field in the same direction.

Here, each of the plurality of magnets may be, for example, an electromagnet. With this configuration, it is possible to generate magnetic fields of different frequencies or different phases at the same position in the radial direction or the circumferential direction by supplying electric power of different frequencies or different phases to the electromagnets and to easily superimpose the generated magnetic fields. Accordingly, it is possible to fix the generated magnetic fields, to change the phases according to a change over time, or to further increase a control width of the magnetic fields using the plurality of magnet units.

The plurality of magnets may be, for example, a combination of an electromagnet and a permanent magnet. The electromagnet may be supplied with electric power from different power supplies. In this case, each magnet unit may include two or more magnets in the direction parallel to the center axis. Each magnet unit may include two or more magnets adjacent to each other in the radial direction or the circumferential direction. Here, “magnets adjacent to each other” means that the magnets adjacent to each other are in a range in which the magnetic fields generated thereby can be considered as a magnetic field generated by one magnet when the magnetic fields generated by the magnets adjacent to each other are superimposed. The magnets adjacent to each other include, for example, a state in which a plurality of magnets are separated by about several mm.

In the plasma processing apparatus according to the aspect of the invention, at least one of the plurality of magnet units may include the electromagnet. The electromagnet may include at least a first electromagnet and a second electromagnet. The first electromagnet may include a first magnetic core and a first coil part wound around the first magnetic core. The second electromagnet may include a second magnetic core and a second coil part wound around the second magnetic core. The first electromagnet and the second electromagnet may be arranged in the radial direction or the circumferential direction, and the first electromagnet and the second electromagnet may generate the magnetic field in the same direction.

Here, the first coil part wound around the first magnetic core means a state in which a plurality of coils constituting the first coil part are wound around the first magnetic core. Similarly, the second coil part wound around the second magnetic core means a state in which a plurality of coils constituting the second coil part are wound around the second magnetic core.

With this configuration, a magnet unit including a combination of a plurality of electromagnets including the first electromagnet and the second electromagnet can be considered as one magnet. It is possible to superimpose magnetic fields generated by the plurality of combined electromagnets and to generate plasma. Since the plurality of electromagnets are arranged in the radial direction or the circumferential direction, intensity centers of the magnetic fields generated by the plurality of magnets can match the positions of a plurality of coil parts including the first coil part and the second coil part. Accordingly, it is possible to realize precise magnetic field control.

In the plasma processing apparatus according to the aspect of the invention, at least one of the plurality of magnet units may include the electromagnet, and the electromagnet may include at least a first electromagnet and a second electromagnet. The first electromagnet may include a first magnetic core and a first coil part wound around the first magnetic core. The second electromagnet may include a second magnetic core and a second coil part wound around the second magnetic core. The first electromagnet and the second electromagnet may be arranged in the direction parallel to the center axis, and the first electromagnet and the second electromagnet may generate the magnetic field in the same direction.

With this configuration, a magnet unit including a combination of a plurality of electromagnets including the first electromagnet and the second electromagnet can be considered as one magnet. It is possible to superimpose magnetic fields generated by the plurality of combined electromagnets and to generate plasma. Since the plurality of electromagnets are arranged in the direction parallel to the center axis, intensity centers of the magnetic fields generated by the plurality of magnets can match the positions of a plurality of coil parts including the first coil part and the second coil part. Accordingly, it is possible to realize precise magnetic field control.

In the plasma processing apparatus according to the aspect of the invention, at least one of the plurality of magnet units may include the electromagnet, and the electromagnet may include a magnetic core, a first coil part wound around the magnetic core, and a second coil part wound around the magnetic core. The first coil part and the second coil part may be arranged in the direction parallel to the center axis, and the first coil part and the second coil part may generate the magnetic field in the same direction.

With this configuration, the intensity centers of the generated magnetic fields can match the positions of the plurality of coil parts including the first coil part and the second coil part. Accordingly, it is possible to realize precise magnetic field control in one magnet unit. In this case, the first coil part and the second coil part may be supplied with currents flowing in the same direction or may be supplied with currents in different directions.

In the plasma processing apparatus according to the aspect of the invention, the plurality of magnet units may generate a rotating magnetic field rotating with respect to the target or an oscillating magnetic field oscillating with respect to the target.

With this configuration, by performing control such that a rotating magnetic field rotating with respect to the target is generated, for example, it is possible to perform a plasma process such as sputtering on a circular substrate used to manufacture a semiconductor device or the like. Accordingly, it is possible to realize a process such as a desired film forming process. By performing control such that an oscillating magnetic field oscillating with respect to the target is generated, for example, it is possible to perform a plasma process such as sputtering on a rectangular substrate used for a flat panel display (FPD) such as a liquid crystal display or an organic EL display. Accordingly, it is possible to form a film with a desired profile on the substrate and to obtain excellent processing characteristics.

The plasma processing apparatus according to the aspect of the invention may further include a cooling mechanism configured to cool the plurality of magnet units.

With this configuration, it is possible to suppress an increase in temperature of the sputtering cathode in the plasma process and to perform the plasma process in a state in which an influence of an increase in temperature of the magnet units is excluded. In this case, since the magnet units can be cooled on the side of the target opposite to the sputtering surface, it is possible to cool the plurality of magnet units without affecting an influence of a coolant on the film formation space in which plasma is generated.

### Advantageous Effects of Invention

With the plasma processing apparatus according to the aspect of the invention, it is possible to provide an apparatus capable of controlling a magnetic field required to perform a desired process in a plasma process such as a film forming process in which the magnetic fields generated by the plurality of magnets change. It is possible to provide an apparatus capable of easily setting currents for controlling a necessary magnetic field and shorten a calculation time required for setting the currents. It is possible to provide an apparatus capable of increasing a control margin for controlling a magnetic field required to perform a desired process.

### BRIEF DESCRIPTION OF DRAWINGS

FIG. 1 A cross-sectional view showing a plasma processing apparatus according to a first embodiment of the invention.

FIG. 2 A plan view schematically showing a sputtering cathode in the plasma processing apparatus according to the first embodiment of the invention.

FIG. 3A A perspective view showing a magnet unit in the plasma processing apparatus according to the first embodiment of the invention.

FIG. 3B A perspective view showing Modified Example 1 of a magnet unit in the plasma processing apparatus according to the first embodiment of the invention.

FIG. 3C A perspective view showing Modified Example 2 of a magnet unit in the plasma processing apparatus according to the first embodiment of the invention.

FIG. 4 A graph showing an example of currents supplied to the magnet units from a magnetic-field generation power supply in the plasma processing apparatus according to the first embodiment of the invention.

FIG. 5 A graph showing an example of currents supplied to the magnet units from the magnetic-field generation power supply in the plasma processing apparatus according to the first embodiment of the invention.

FIG. 6 A graph showing an example of currents supplied to the magnet units from the magnetic-field generation power supply in the plasma processing apparatus according to the first embodiment of the invention.

FIG. 7 A diagram schematically showing an example of control in an outermost magnet pattern in the plasma processing apparatus according to the first embodiment of the invention.

FIG. 8 A cross-sectional view showing a plasma processing apparatus according to a second embodiment of the invention.

FIG. 9 A plan view schematically showing a sputtering cathode in a plasma processing apparatus according to a third embodiment of the invention.

FIG. 10 A plan view schematically showing a sputtering cathode in a plasma processing apparatus according to a fourth embodiment of the invention.

FIG. 11 A plan view schematically showing a sputtering cathode in a plasma processing apparatus according to a fifth embodiment of the invention.

FIG. 12 A diagram schematically showing an example of control in an outermost magnet pattern in the plasma processing apparatus according to the fifth embodiment of the invention.

FIG. 13 A graph showing an example of the invention.

FIG. 14 A graph showing an example of the invention.

FIG. 15 A graph showing an example of the invention.

FIG. 16 A graph showing an example of the invention.

FIG. 17 A graph showing an example of the invention.

FIG. 18 A graph showing an example of the invention.

FIG. 19 A graph showing an example of the invention.

FIG. 20 A graph showing an example of the invention.

FIG. 21 A graph showing an example of the invention.

FIG. 22 A graph showing an example of the invention.

FIG. 23 A graph showing an example of the invention.

FIG. 24 A graph showing an example of the invention.

### DESCRIPTION OF EMBODIMENTS

Hereinafter, a plasma processing apparatus according to an embodiment of the invention will be described with reference to the accompanying drawings.

In the following description of embodiments, constituents having the same or similar functions will be referred to by the same reference signs. Repeated description of the constituents may be omitted. The drawings are schematic or conceptual, and a relationship between thicknesses and widths of each part, ratios in sizes between the parts, and the like are not necessarily the same as in the real world.

Ordinal numbers such as “first”, “second”, and “third” may be used in the following description of the embodiments. These ordinal numbers do not represent the numbers of members to which the ordinal numbers are added. The ordinal numbers may be used to indicate that a plurality of members are separate.

A wording “opposite” indicates a positional relationship between two members. This positional relationship indicates that the two members are opposite to each other and also indicates that another member is interposed between the two members. The same analysis is also applied to wordings “provided”, “arrange”, and “connect”.

In description of a plasma processing apparatus, wordings “thickness direction”, “radial direction”, and “circumferential direction” are used as terms indicating directions.

The thickness direction corresponds to a thickness direction of a target T. In the embodiments, the thickness direction corresponds to, for example, a Z direction. The thickness direction and the Z direction may be referred to using a “plan view”.

The radial direction corresponds to a radial direction extending from the center of a sputtering surface TS of the target T. In the embodiments, the radial direction corresponds to, for example, an X direction and a Y direction.

The circumferential direction corresponds to a circumferential direction of the sputtering surface TS around a center axis Bo extending in the thickness direction (the Z direction) of the target T.

The wordings “thickness direction”, “radial direction”, and “circumferential direction” are wordings used to describe positional relationships between a plurality of members constituting each plasma processing apparatus or shapes or structures of the plurality of members and do not define postures of the members.

### First Embodiment

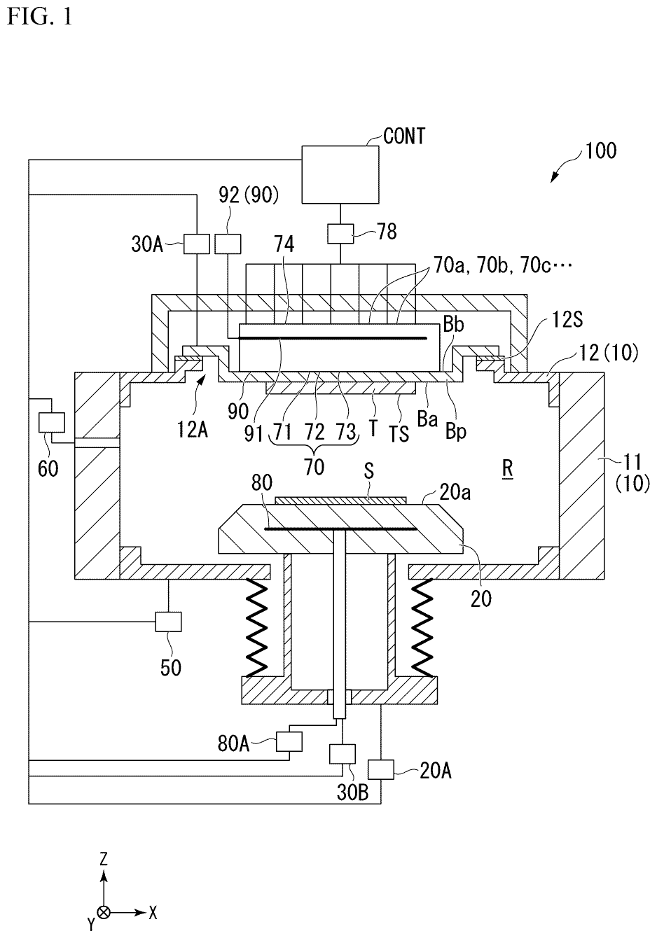

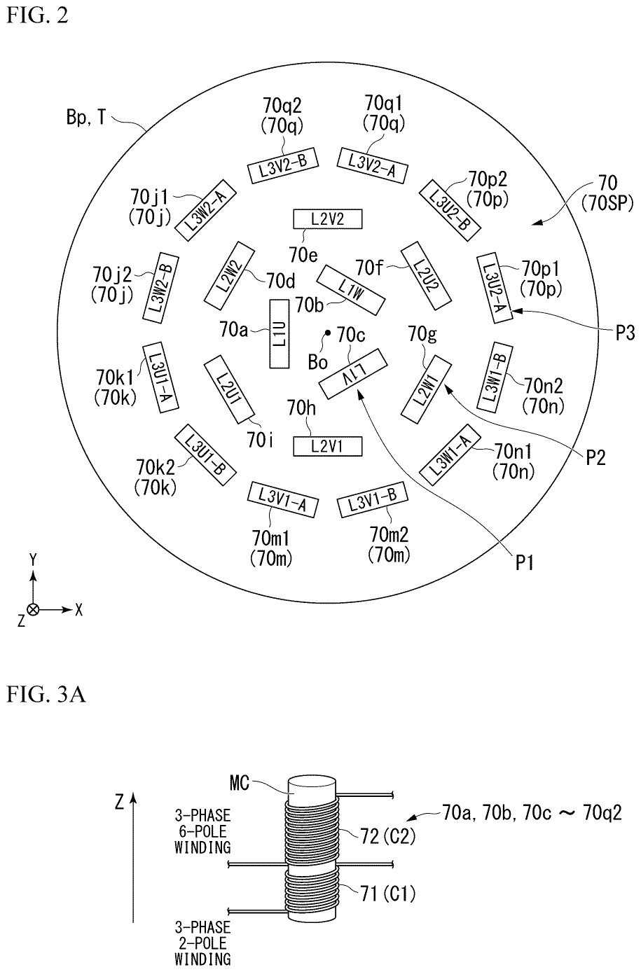

FIG. 1 is a cross-sectional view showing a plasma processing apparatus according to a first embodiment. FIG. 2 is a plan view schematically showing a sputtering cathode in the plasma processing apparatus according to the present embodiment. In FIG. 1, reference sign 100 denotes a plasma processing apparatus.

### <Sputtering Apparatus>

In the first embodiment described below, a magnetron sputtering apparatus will be described as an example of the plasma processing apparatus. This magnetron sputtering apparatus is a parallel-plate sputtering apparatus using a sputtering down system. The magnetron sputtering apparatus uses a rotary magnetron cathode (a sputtering cathode). Here, the sputtering cathode means a group of members (such as a target or a magnetic circuit) constituting a cathode side of the plasma processing apparatus. In the following description, the magnetron sputtering apparatus may be simply referred to as a plasma processing apparatus or a sputtering apparatus.

The plasma processing apparatus 100 according to the present embodiment is a film-formation apparatus that is used to form a film on a circular substrate such as a silicon wafer in semiconductor manufacturing or the like. As shown in FIG. 1, the plasma processing apparatus 100 according to the present embodiment includes a vacuum chamber 10, a substrate stage 20 (a substrate support part), a T/S changing mechanism 20A, a sputtering power supply 30A (a plasma generation power supply) that applies plasma supply power to the target T, a bias power supply 30B that applies electric power to the substrate stage 20, a vacuum pump 50 (a gas-atmosphere setting part) that is a depressurization mechanism, a gas supply part 60 (a gas-atmosphere setting part) that supplies a process gas, a sputtering cathode 70, a coil power supply 78 (a magnetic-field generation power supply), a heater 80 (a temperature setting mechanism), a cooling mechanism 90, a target T, a backing plate Bp, and a control device CONT.

### <Vacuum Chamber>

The vacuum chamber 10 includes a lower chamber 11 and an upper chamber 12. The upper chamber 12 includes an opening 12A. The opening 12A is a part in which a backing plate Bp which will be described later is provided. The internal space of the plasma processing apparatus 100 which is surrounded by the vacuum chamber 10 and the backing plate Bp is a film formation space R. A gate valve that is not shown in the drawings is provided in the lower chamber 11. The gate valve is disposed between two vacuum chambers. The gate valve can be opened and closed in a state in which a vacuum level of the film formation space R is maintained. In the state in which the gate valve is open, a substrate S can be carried between the outside and the inside of the film formation space R.

### <Substrate Stage>

The substrate stage 20 is an example of a substrate support part.

The substrate stage 20 is configured to support a substrate S. The substrate stage 20 is disposed to face the target T. The substrate stage 20 is disposed in the vacuum chamber 10 and is formed of, for example, an aluminum alloy which is a conductive member. The substrate stage 20 includes a substrate mounting surface 20a. A substrate S is mounted on the substrate mounting surface 20a. The heater 80 serving as a temperature setting mechanism may be disposed inside of the substrate stage 20 in the thickness direction. The heater 80 is provided to have a larger diameter than that of the substrate S in a plan view. The heater 80 is connected to a heater power supply 80A. The heater 80 can set the temperature of the substrate S through heating or the like.

### <T/S Changing Mechanism>

The T/S changing mechanism 20A is configured to adjust a distance between a target T and a substrate S (T/S distance) which will be described later by moving the substrate stage 20 in the vertical direction (the Z direction). A known mechanism using a stepping motor or the like is used as a drive mechanism of the T/S changing mechanism 20A.

### <Sputtering Power Supply>

The sputtering power supply 30A is an example of a plasm generation power supply.

The sputtering power supply 30A is, for example, a DC power supply. The sputtering power supply 30A is provided outside of the vacuum chamber 10 and is electrically connected to the backing plate Bp which will be described later. A known DC/AC power supply can be employed as the sputtering power supply 30A. The sputtering power supply 30A can also supply electric power in which different frequencies are superimposed to the backing plate Bp. The sputtering power supply 30A is configured to generate plasm inside of the vacuum chamber 10 by supplying electric power to the target T.

### <Bias Power Supply>

The bias power supply 30B is provided, for example, outside of the vacuum chamber 10. The bias power supply 30B is electrically connected to the substrate stage 20 provided inside the vacuum chamber 10 via a matching box and a wire, which are not shown in the drawings. The bias power supply 30B can supply known high-frequency power such as 13.56 MHz to the substrate stage 20. The bias power supply 30B can also supply, for example, bias-frequency power such as 2 MHz to the substrate stage 20.

The configurations of the sputtering power supply 30A and the bias power supply 30B are not limited to a DC power supply (DC) or a high-frequency power supply (RF). A pulse-DC, a DC+RF, or the like can be employed in addition to the DCC and the RF.

The sputtering power supply 30A and the bias power supply 30B constitute a plasma generation power supply for generating plasma inside of the vacuum chamber 10.

The plasma processing apparatus 100 may not include the bias power supply 30B. In this case, the substrate stage 20 may be set to a floating potential or a ground potential.

### <Vacuum Pump>

The vacuum pump 50 is an example of a gas-atmosphere setting part.

The vacuum pump 50 is connected to an exhaust port formed in the vacuum chamber 10 via a pressure control value and a pipe, which are not shown in the drawings.

By driving the vacuum pump 50, the inside of the vacuum chamber 10 can be depressurized, and the vacuum chamber 10 can be maintained in a vacuum state. The vacuum pump 50 can exhaust gas remaining inside of the vacuum chamber 10 while performing a process or after the process has ended. By driving the vacuum pump 50 and the pressure control valve in a state in which a process gas has been supplied into the vacuum chamber 10, it is possible to adjust the pressure in the vacuum chamber 10 according to process conditions.

### <Gas Supply Part>

The gas supply part 60 is an example of a gas-atmosphere setting part.

The gas supply part 60 is connected to a gas supply port formed in the vacuum chamber 10 via a mass flow controller and a pipe, which are not shown in the drawings. Known gas which is used for sputtering is used as the gas supplied from the gas supply part 60 to the vacuum chamber 10. For example, argon, nitrogen, nitrogen-containing gas, oxygen, oxygen-containing gas, and other gas are used. By driving the vacuum pump 50 and the gas supply part 60, gas is supplied into the vacuum chamber 10, gas is exhausted from the vacuum chamber 10, and a gas atmosphere in the film formation space R is set.

### <Sputtering Cathode>

The sputtering cathode 70 includes the backing plate Bp, the target T, a plurality of magnet units 70a, 70b, 70c, . . . , and the cooling mechanism 90.

### <Backing Plate>

The backing plate Bp is disposed in the opening 12A of the upper chamber 12. The backing plate Bp is fixed to the upper chamber 12 via a seal member 12S. The backing plate Bp includes a bottom surface Ba and a top surface Bb.

The bottom surface Ba faces the film formation space R. The bottom surface Ba is a surface to which the target T is fixed. The top surface Bb is located on the side (a rear side) opposite to the bottom surface Ba. A plurality of magnet units 70a, 70b, 70c, . . . including a first electromagnet 71, a second electromagnet 72, and a third electromagnet 73 which will be described later are arranged along the top surface Bb.

In the top surface Bb, an insulating member of resin or the like may be formed on the surface. The insulating member may be an insulating film or an isolation film disposed in the top surface Bb of the backing plate Bp. The insulating member may be an insulating film obtained by performing surface treatment (an insulating process) on the top surface Bb of the backing plate Bp. The insulating member may cover the magnet units 70a, 70b, 70c, . . . together. The insulating member may be configured to cover the first electromagnet 71, the second electromagnet 72, and the third electromagnet 73. The insulating member may be configured to cover a magnet 74 (a permanent magnet). In this case, the insulating member constitutes the cooling mechanism 90.

### <Target>

The target T is disposed inside of the vacuum chamber 10. The target T has a circular shape in a plan view. A type of metal constituting the target T is set according to a composition of a film to be formed and is not particularly limited. The metal material may be a single material or an alloy in which a plurality of materials are contained at predetermined proportions. The target T includes a sputtering surface TS which is opposite to a substrate S in the film formation space R. The target T includes a center axis Bo passing through the center of the circular shape.

The center axis Bo of the target T can be orthogonal to the sputtering surface TS. The center axis Bo extends in the Z direction as shown in FIG. 1. The center axis Bo matches the center axis Bo of the sputtering surface TS. The center axis Bo matches the center axis (see FIG. 2) of the backing plate Bp. In the following description, the center axis of the target T, the center axis of the sputtering surface TS, and the center axis of the backing plate Bp are referred to as a center axis Bo.

Here, “plan view” means a plane when seen from below in the Z direction shown in FIG. 1. The Z direction is the same as the direction indicated by reference sign Z in FIG. 1.

### <Magnet Unit>

The plurality of magnet units 70a, 70b, 70c, . . . constitute a magnetic circuit.

The plurality of magnet units 70a, 70b, 70c, . . . are in contact with the top surface Bb of the backing plate Bp and is disposed outside of the film formation space R. In other words, the plurality of magnet units 70a, 70b, 70c, . . . are located opposite to the sputtering surface TS.

The plurality of magnet units 70a, 70b, 70c, . . . are provided to generate a leakage magnetic field obtained by superimposing a plurality of magnetic fields generated from the plurality of magnet units 70a, 70b, 70c, . . . in the film formation space R facing the sputtering surface TS. The plurality of magnet units 70a, 70b, 70c, . . . are configured to change the leakage magnetic field in the Z direction, the radial direction, and the circumferential direction.

Each of the plurality of magnet units 70a, 70b, 70c, . . . is provided to generate a magnetic field in a direction parallel to the center axis Bo. Two magnet units adjacent to each other out of the plurality of magnet units 70a, 70b, 70c, . . . are disposed to be separated from each other in the radial direction.

Two magnet units adjacent to each other out of the plurality of magnet units 70a, 70b, 70c, . . . are disposed to be separated from each other in the circumferential direction.

In a coil of a coil part constituting each magnet of the plurality of magnet units 70a, 70b, 70c, . . . are set to correspond to a magnetic field to be generated in each of the magnet units 70a, 70b, 70c, . . . .

The coil part constituting each magnet of the plurality of magnet units 70a, 70b, 70c, . . . has a winding number, a fixing position, and a size (in a plan view) which are necessary for a magnetic circuit constituted by the magnet units 70a, 70b, 70c, . . . .

### <Arrangement Pattern of Magnet Units>

As shown in FIG. 2, the plurality of magnet units 70a, 70b, 70c, . . . are arranged to form a first magnet pattern P1 (a first arrangement line), a second magnet pattern P2 (a second arrangement line), and a third magnet pattern P3 (a third arrangement line) around the center axis Bo of the backing plate BP in a plan view.

The first magnet pattern P1, the second magnet pattern P2, and the third magnet pattern P3 are formed as multiple rings around the center axis Bo in a plan view. Each of the first magnet pattern Pt, the second magnet pattern P2, and the third magnet pattern P3 is arranged in a ring shape surrounding the center axis Bo in a plan view. Regarding the size in the radial direction, the first magnet pattern P1, the second magnet pattern P2, and the third magnet pattern P3 have different sizes at positions relative to the center axis Bo in a plan view.

The first magnet pattern P1 and the second magnet pattern P2 are separated from each other in the radial direction from the center axis Bo in a plan view. The second magnet pattern P2 is disposed on an outer side in the radial direction from the center axis Bo than the first magnet pattern P1 in a plan view. The second magnet pattern P2 and the third magnet pattern P3 are separated from each other in the radial direction from the center axis Bo in a plan view. The third magnet pattern P3 is disposed on an outer side in the radial direction from the center axis Bo than the second magnet pattern P2 in a plan view.

The first magnet pattern P1 is disposed closest to the center axis Bo in the radial direction in a plan view. The first magnet pattern P1 is disposed on the innermost side in the radial direction in a plan view. In the present embodiment, the third magnet pattern P3 is disposed closest to the outermost circumference of the target T in a plan view. The third magnet pattern P3 is disposed to be most away from the center axis Bo in the radial direction in a plan view.

As shown in FIG. 2, the first magnet pattern P1 includes a magnet unit 70a, a magnet unit 70b, and a magnet unit 70c. The magnet unit 70a, the magnet unit 70b, and the magnet unit 70c are separated by the same distance from the position of the center axis Bo in the radial direction in a plan view. The magnet unit 70a, the magnet unit 70b, and the magnet unit 70c are separated by the same distance from each other with respect to the position of the center axis Bo in the circumferential direction.

The magnet unit 70a, the magnet unit 70b, and the magnet unit 70c are disposed to form a circle around the center axis Bo in a plan view. The first magnet pattern P1 includes the magnet unit 70a, the magnet unit 70b, and the magnet unit 70c. Accordingly, the first magnet pattern P1 forms a ring-shaped pattern to form a circle around the center axis Bo in a plan view.

The second magnet pattern P2 includes a magnet unit 70d, a magnet unit 70e, a magnet unit 70f, a magnet unit 70g, a magnet unit 70h, and a magnet unit 70i. The magnet unit 70d, the magnet unit 70e, the magnet unit 70f, the magnet unit 70g, the magnet unit 70h, and the magnet unit 70i are separated by the same distance from the position of the center axis Bo in the radial direction in a plan view. The magnet unit 70d, the magnet unit 70e, the magnet unit 70f, the magnet unit 70g, the magnet unit 70h, and the magnet unit 70i are separated by the same distance from each other with respect to the position of the center axis Bo in the circumferential direction.

The magnet unit 70d, the magnet unit 70e, the magnet unit 70f, the magnet unit 70g, the magnet unit 70h, and the magnet unit 70i are disposed to form a circle around the center axis Bo in a plan view. The magnet unit 70d, the magnet unit 70e, the magnet unit 70f, the magnet unit 70g, the magnet unit 70h, and the magnet unit 70i are disposed on an outer side in the radial direction from the center axis BO than the magnet unit 70a, the magnet unit 70b, and the magnet unit 70c.

The second magnet pattern P2 includes the magnet unit 70d, the magnet unit 70e, the magnet unit 70f, the magnet unit 70g, the magnet unit 70h, and the magnet unit 70i. Accordingly, the second magnet pattern P2 forms a ring-shaped pattern to form a circle around the center axis Bo in a plan view.

The third magnet pattern P3 includes a magnet unit 70j, a magnet unit 70k, a magnet unit 70m, a magnet unit 70n, a magnet unit 70p, and a magnet unit 70q. The magnet unit 70j, the magnet unit 70k, the magnet unit 70m, the magnet unit 70n, the magnet unit 70p, and the magnet unit 70q are separated by the same distance from the position of the center axis Bo in the radial direction in a plan view. The magnet unit 70j, the magnet unit 70k, the magnet unit 70m, the magnet unit 70n, the magnet unit 70p, and the magnet unit 70q are separated by the same distance from each other with respect to the position of the center axis Bo in the circumferential direction.

The magnet unit 70j, the magnet unit 70k, the magnet unit 70m, the magnet unit 70n, the magnet unit 70p, and the magnet unit 70q are disposed to form a circle around the center axis Bo in a plan view. The magnet unit 70j, the magnet unit 70k, the magnet unit 70m, the magnet unit 70n, the magnet unit 70p, and the magnet unit 70q are disposed on an outer side in the radial direction from the center axis BO than magnet unit 70d, the magnet unit 70e, the magnet unit 70f, the magnet unit 70g, the magnet unit 70h, and the magnet unit 70i.

Each of the magnet unit 70j, the magnet unit 70k, the magnet unit 70m, the magnet unit 70n, the magnet unit 70p, and the magnet unit 70q includes two electromagnet parts which are separated in the circumferential direction around the position of the center axis Bo in a plan view.

As shown in FIG. 2, the magnet unit 70j includes an electromagnet part 70j1 and an electromagnet part 70j2 which are separated in the circumferential direction. The electromagnet part 70j1 and the electromagnet part 70j2 are disposed to be separated in the circumferential direction in a plan view. A distance by which the electromagnet part 70j1 and the electromagnet part 70j2 are separated in the circumferential direction is the same as a distance by which the electromagnet part 70j2 and the electromagnet part 70k1 are separated in the circumferential direction. The distance by which the electromagnet part 70j1 and the electromagnet part 70j2 are separated in the circumferential direction is the same as a distance by which the electromagnet part 70j1 and the electromagnet part 70q2 are separated in the circumferential direction.

Each of the electromagnet part 70j1 and the electromagnet part 70j2 has the same configuration as the magnet units 70a to 70i. That is, the magnet unit 70j of the third magnet pattern P3 has a configuration in which two magnet units constituting the first magnet pattern P1 and the second magnet pattern P2 located on an inner side in the radial direction from the center axis are assembled.

As shown in FIG. 2, similarly, the magnet unit 70k includes an electromagnet part 70k1 and an electromagnet part 70k2 which are separated in the circumferential direction. The electromagnet part 70k1 and the electromagnet part 70k2 are disposed to be separated in the circumferential direction in a plan view. A distance by which the electromagnet part 70k1 and the electromagnet part 70k2 are separated in the circumferential direction is the same as a distance by which the electromagnet part 70k2 and the electromagnet part 70m1 are separated in the circumferential direction. The distance by which the electromagnet part 70j1 and the electromagnet part 70j2 are separated in the circumferential direction is the same as the distance by which the electromagnet part 70k1 and the electromagnet part 70j2 are separated in the circumferential direction.

Each of the electromagnet part 70k1 and the electromagnet part 70k2 has the same configuration as the magnet units 70a to 70i. That is, the magnet unit 70k of the third magnet pattern P3 has a configuration in which two magnet units constituting the first magnet pattern P1 and the second magnet pattern P2 located on an inner side in the radial direction from the center axis are assembled.

Each of the magnet unit 70, the magnet unit 70n, the magnet unit 70p, and the magnet unit 70q includes two electromagnet parts which are separated in the circumferential direction similarly to the magnet unit 70j and the magnet unit 70k. Each of the electromagnet part is referred to by a reference sign in which 1 or 2 is added to reference signs m, n, p, and q indicating the magnet units.

The third magnet pattern P3 includes the electromagnet part 70j1, the electromagnet part 70j2, the electromagnet part 70k1, the electromagnet part 70k2, the electromagnet part 70m1, the electromagnet part 70m2, the electromagnet part 70n1, the electromagnet part 70n2, the electromagnet part 70n1, the electromagnet part 70p2, the electromagnet part 70q1, and the electromagnet part 70q2. Accordingly, the third magnet pattern P3 forms a ring-shaped pattern to form a circle around the center axis Bo in a plan view.

Polarities of the first magnet pattern P1, the second magnet pattern P2, and the third magnet pattern P3 are set, for example, to correspond to an N pole, an S pole, and an N pole. Accordingly, a magnetic circuit for locking plasma is formed.

In at least one of the radial direction and the circumferential direction with respect to the position of the center axis Bo, the magnet units 70a to 70q (the electromagnet part 70q2) may be disposed at equal intervals. The magnet units 70a to 70q (the electromagnet part 70q2) have the same configuration but are disposed at different positions. The magnet units 70a to 70q (the electromagnet part 70q2) may have different configurations and disposed at a predetermined position.

The magnet units 70a to 70q (the electromagnet part 70q2) can generate a magnetic field in the Z direction. The magnet units 70a to 70q (the electromagnet part 70q2) can generate the magnetic fields in directions parallel to each other. The magnet units 70a to 70q (the electromagnet part 70q2) can generate the magnetic fields having characteristics such as different intensities as long as they can generate the magnetic fields in the directions parallel to each other.

In other words, at least one of the magnet units 70a to 70q (the electromagnet part 70q2) includes a plurality of magnet, and the plurality of magnets can generate magnetic fields in the same direction.

The magnet units 70a to 70q (the electromagnet part 70q2) can generate a rotating magnetic field rotating with respect to the target T or an oscillating magnetic field oscillating with respect to the target T.

Each of the magnet units 70a to 70q (the electromagnet part 70q2) is constituted by a combination of electromagnets. For example, each of the magnet units 70a to 70q (the electromagnet part 70q2) includes a magnetic core (a core or an iron core) extending in the Z direction.

As will be described later, the magnet units 70a to 70q (the electromagnet part 70q2) has a configuration of one of a permanent magnet, an electromagnet, a combination of a plurality of permanent magnets, a combination of a plurality of electromagnets, and a combination of a permanent magnet and an electromagnet.

### <Configuration of Magnet Unit>

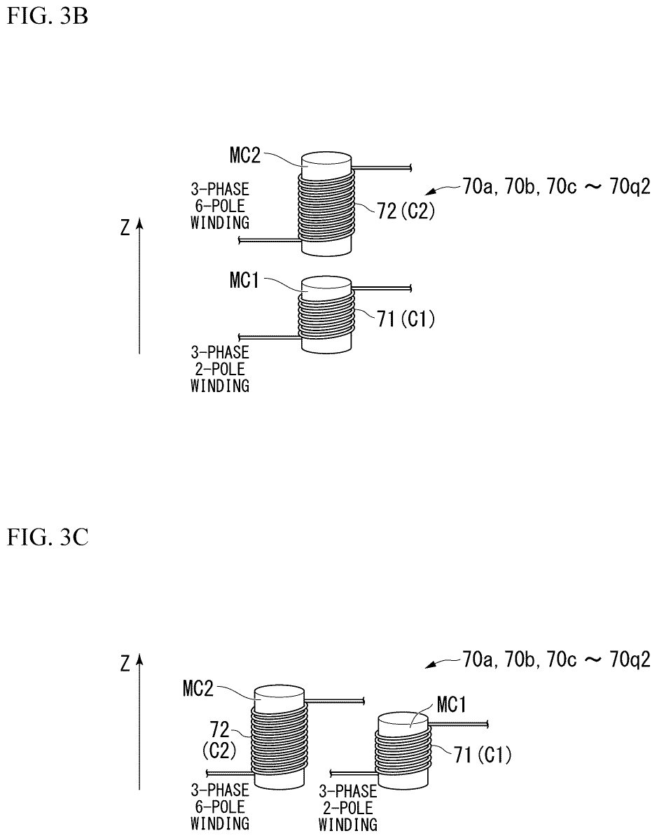

FIG. 3A is a perspective view schematically showing a magnet unit (an electromagnet part) in the plasma processing apparatus according to the present embodiment. In the following description, each of the magnet units 70a to 70q (the electromagnet part 70q2) may be simply referred to as a “magnet unit”.

In the present embodiment, each of the magnet units 70a to 70q (the electromagnet part 70q2) includes a first electromagnet 71 and a second electromagnet 72 as shown in FIG. 3A. The magnet units 70a to 70q (the electromagnet part 70q2) constitute a magnet.

The first electromagnet 71 and the second electromagnet 72 are disposed coaxially in the Z direction as shown in FIG. 3A. The first electromagnet 71 and the second electromagnet 72 are disposed in a magnet unit to have an axis extending in the direction perpendicular to a plane of the target T. The first electromagnet 71 and the second electromagnet 72 are disposed along the top surface Bb parallel to the plane of the target T.

The second electromagnet 72 is close to the top surface Bb when seen in the X direction or the Y direction. The second electromagnet 72 may be in contact with the top surface Bb when seen in the X direction or the Y direction. The first electromagnet 71 is more separated from the top surface Bb in the Z direction than the second electromagnet 72. The first electromagnet 71 and the second electromagnet 72 are adjacent in the Z direction. The first electromagnet 71 and the second electromagnet 72 are in a state in which coils are stacked in the Z direction. The first electromagnet 71 and the second electromagnet 72 have a configuration in which coils are double-wound. The winding number ratio of the double-wound coils of the first electromagnet 71 and the second electromagnet 72 can be changed within 1:1 to 1:9.

As shown in FIG. 2, the sputtering cathode 70 includes a plate-shaped support member 70SP which has an area larger than or equal to that of the target T and which is provided in parallel to the sputtering surface TS. The electromagnets 71 and 72 are provided in the support member 70SP. In the support member 70SP, coil parts C1 and C2 are provided on a magnetic core MC. A coil of each of the coil parts C1 and C2 is wound around the magnet core MC in a predetermined winding number and a predetermined arrangement. Accordingly, two electromagnets 71 and 72 are provided in one magnet unit as shown in FIG. 3A. The number of electromagnets is not limited to two. Three or more electromagnets may be provided in one magnet unit.

The first electromagnet 71 includes a first coil part C1 which is electrically connected to the coil power supply 78. The first electromagnet 71 is supplied with an AC current from the coil power supply 78.

A coil constituting the first coil part C1 of the first electromagnet 71 is, for example, three-phase two-pole coil. In other words, a three-phase AC current flows in the coil of the first coil part C1, and the first electromagnet 71 is configured to generate two magnetic poles.

The second electromagnet 72 includes a second coil part C2 which is electrically connected to the coil power supply 78. The second electromagnet 72 is supplied with an AC current from the coil power supply 78.

A coil constituting the second coil part C2 of the second electromagnet 72 is, for example, three-phase six-pole coil. In other words, a three-phase AC current flows in the coil of the second coil part C2, and the second electromagnet 72 is configured to generate six magnetic poles.

The first coil part C1 of the first electromagnet 71 and the second coil part C2 of the second electromagnet 72 are wound around the same one magnetic core MC. Here, the magnetic core of the first electromagnet 71 and the magnetic core of the second electromagnet 72 are shared. The magnetic core of the first electromagnet 71 and the magnetic core of the second electromagnet 72 may be formed to be separate from each other as will be described later.

In other words, an electromagnet constituting a magnet unit includes one magnetic core MC, a first coil part C1 wound around the magnetic core MC, and a second coil part C2 wound around the magnet core MC. The magnetic core MC has a cylindrical shape with the same diameter. The first coil part C1 and the second coil part C2 are arranged in the direction parallel to the center axis Bo, and the first coil part C1 and the second coil part C2 are configured to generate magnetic fields in the same direction.

The magnetic core MC on which the first coil part C1 and the second coil part C2 are wound has the same diameter in the Z direction. The diameter of a part of the magnetic core MC on which the first coil part C1 is wound and the diameter of a part of the magnetic core MC on which the second coil part C2 is wound may be different.

Each coil of the first coil part C1 and the second coil part C2 has a free end. The free ends protrude outward from the vacuum chamber 10. The first coil part C1 and the second coil part C2 are connected to the coil power supply 78.

### <Modified Example 1 of Magnet Unit>

In the example shown in FIG. 3A, a structure in which a plurality of wound coil parts are wound around one magnetic core MC is described, but the number of magnetic cores MC may be set according to the number of coil parts.

For example, as shown in FIG. 3B, electromagnets constituting a magnet unit include a first electromagnet 71 and a second electromagnet 72. The first electromagnet 71 includes a first magnetic core MC1 and a first coil part C1 wound around the first magnetic core MC1. The second electromagnet 72 includes a second magnetic core MC2 and a second coil part C2 wound around the second magnetic core MC2. The first electromagnet 71 and the second electromagnet 72 are arranged in the direction parallel to the center axis Bo. The first electromagnet 71 and the second electromagnet 72 are configured to generate magnetic fields in the same direction.

The diameter of the first magnetic core MC1 and the diameter of the second magnetic core MC2 may be the same or different from each other.

### <Modified Example 2 of Magnet Unit>

In the example shown in FIG. 3B, a structure in which two magnetic cores are arranged in the direction parallel to the center axis Bo is described, but the number of two magnetic cores may be arranged in the radial direction or the circumferential direction.

For example, as shown in FIG. 3C, electromagnets constituting a magnet unit include a first electromagnet 71 and a second electromagnet 72. The first electromagnet 71 includes a first magnetic core MC1 and a first coil part C1 wound around the first magnetic core MC1. The second electromagnet 72 includes a second magnetic core MC2 and a second coil part C2 wound around the second magnetic core MC2. The first electromagnet 71 and the second electromagnet 72 are arranged in the radial direction or the circumferential direction. The first electromagnet 71 and the second electromagnet 72 are configured to generate magnetic fields in the same direction.

The diameter of the first magnetic core MC1 and the diameter of the second magnetic core MC2 may be the same or different from each other.

### <Cooling Mechanism>

The cooling mechanism 90 constituting the sputtering cathode 70 will be described below with reference back to FIG. 1.

The cooling mechanism 90 is provided in the top surface Bb of the backing plate Bp.

The cooling mechanism 90 includes a cooling pipe 91 and a coolant supply part 92 that supplies a coolant to the cooling pipe 91. The cooling pipe 91 allows a fluid which is a coolant to flow in a member between a plurality of magnets constituting the magnet units 70a, 70b, 70c, . . . .

When the magnets of the magnet units 70a, 70b, 70c, . . . are covered by an insulating member of a resin or the like, the cooling mechanism 90 may use a space formed on the top surface Bb of the backing plate Bp as the cooling pipe 91. In this case, a coolant can be directly supplied to that space. The insulating member of a resin or the like covering the magnets may be used as the cooling pipe 91. Air may be used as the coolant, and the coolant supply part 92 may be allowed to serve as a fan. The cooling mechanism 90 can cool the magnets by allowing the coolant to flow in the cooling pipe 91 disposed between the plurality of magnets constituting the magnet units 70a, 70b, 70c, . . . . In this case, a coolant flow channel which is the cooling pipe 91 may be formed in the insulating member of a resin or the like. A fluid such as water or oil may be used as the coolant, and the coolant supply part 92 may be used as a pressurization pump.

### <Coil Power Supply>

The coil power supply 78 is an example of a magnetic-field generation power supply.

The coil power supply 78 is electrically connected to the magnet units 70a, 70b, 70c, . . . via wires or the coils of the coil parts. The coil power supply 78 is configured to supply electric power to a plurality of magnet units 70a, 70b, 70c, . . . . Particularly, the coil power supply 78 supplies electric power to the first electromagnets 71 (electromagnets) and the second electromagnets 72 (electromagnets) constituting the plurality of magnet units 70a, 70b, 70c, . . . as will be described later (see FIG. 2).

Accordingly, the coil power supply 78 generates magnetic fields in the plurality of magnet units 70a, 70b, 70c, . . . . Here, electric power supplied from the coil power supply 78 to the plurality of magnet units 70a, 70b, 70c, . . . may be referred to as magnetic field generation power.

The coil power supply 78 can independently control currents and voltages for each of a plurality of coil parts (electromagnets) constituting the magnetic circuit in the first magnet pattern P1 (the first arrangement line), the second magnet pattern P2 (the second arrangement line), and the third magnet pattern P3 (the third arrangement line). The magnet patterns P1, P2, and P3 are constituted by combinations of the magnet units 70a, 70b, 70c, . . . .

FIG. 1 schematically shows a connection state in which the coil power supply 78 is connected to the magnet units 70a, 70b, 70c, . . . at a plurality of positions, but a connection structure for connecting the magnet units 70a, 70b, 70c, . . . to the coil power supply 78 is not limited to the structure shown in FIG. 1.

The coil power supply 78 is connected to the plurality of electromagnets 71 and 72 at one position, but a configuration in which the power supply is connected to the first electromagnet 71 and the second electromagnet 72 may be employed. The coil power supply 78 may be appropriately connected to one electromagnet or may be connected to two or more electromagnets.

For example, in the plurality of magnet units 70a, 70b, 70c, . . . , the coil power supply 78 can supply a three-phase AC current to the first electromagnet 71 and the second electromagnet 72 and supply a DC current to a third electromagnet 73 which will be described later.

The coil power supply 78 can supply currents and voltages to the first electromagnet 71, the second electromagnet 72, and the third electromagnet 73 after performing control such that magnitudes, directions, frequencies, phases, amplitude, DC, AC, and the like of the currents and the voltages are different or synchronized in the plurality of electromagnets. At this time, the currents and the voltages may be supplied to the plurality of magnet units 70a, 70b, 70c, . . . after performing control such that magnitudes, directions, frequencies, phases, amplitude, DC, AC, and the like of the currents and the voltages are different or synchronized in the individual electromagnets.

Referring to FIGS. 3A to 3C, the coil power supply 78 can supply a current of a predetermined current value to the first coil part C1 and the second coil part C2 and can also change the direction of the current. In other words, in each of the magnet units 70a to 70q (the electromagnet part 70q2), the coil power supply 78 can control a current supplied to the first coil part C1 of the first electromagnet 71 and a current supplied to the second coil part C2 of the second electromagnet 72.

The coil power supply 78 can supply currents of different current values to the first electromagnet 71 and the second electromagnet 72 and supply AC currents of different phases.

The coil power supply 78 can supply a current of a predetermined frequency and a current of predetermined amplitude to a plurality of first coil parts C1 and a plurality of second coil parts C2 which are included in the sputtering cathode 70. The coil power supply 78 can locally apply a leakage magnetic field of a balanced closed loop to the film formation space R facing the sputtering surface TS of the target T by controlling the currents for the plurality of first coil parts C1 and the currents for the plurality of second coil parts C2. A known power supply including a predetermined power supply circuit or a switching transistor can be used as the coil power supply 78.

### <Control Device>

The control device CONT is a device that controls the plasma processing apparatus 100. The control device CONT is electrically connected to the sputtering power supply 30A supplying electric power to the target T, the bias power supply 30B supplying electric power to the substrate stage 20, the T/S changing mechanism 20A, the vacuum pump 50, the gas supply part 60, the heater power supply 80A, and the coil power supply 78.

The control device CONT is, for example, a computer including a circuit board on which electronic circuitry is formed. The electronic circuitry includes, for example, an integrated circuit such as a large-scale integrated circuit (LSI) or an application-specific integrated circuit (ASIC). The control device CONT includes, for example, an arithmetic operation device, a storage device, and a communication device. The arithmetic operation device processes various types of information in accordance with a plurality of process steps in the plasma processing apparatus 100. Various types of information before they are processed by the arithmetic operation device and various types of information after they are processed by the arithmetic operation device are stored in the storage device. Computer programs for causing the plasma processing apparatus 100 to perform the plurality of process steps are stored in the storage device. The storage device may be, for example, a known storage medium. The communication device performs communication between an external device other than the plasma processing apparatus 100 and the plasma processing apparatus 100. Operations of various members, devices, and mechanisms constituting the plasma processing apparatus 100 are controlled by the control device CONT. Control of the coil power supply 78 using the control device CONT will be described later.

### <Control Method Using Control Device>

The plasma processing apparatus 100 according to the present embodiment is controlled by the control device CONT. A case in which a sputtering process is performed using the plasma processing apparatus 100 will be described below. In the film formation space R of the plasma processing apparatus 100, a predetermined vacuum level is maintained by driving the vacuum pump 50 in advance. Thereafter, in a state in which the gate valve is open, a substrate S is carried from the outside to the inside of the film formation space R using a carrying arm which is not shown in the drawings. The carrying arm mounts the substrate S on the substrate mounting surface 20a of the substrate stage 20. In the substrate stage 20 on which the substrate S has been mounted, the temperature of the substrate S is controlled using the heater 80 supplied with electric power from the heater power supply 80A.

In this state, the T/S changing mechanism 20A is driven, and the distance between the target T and the substrate S is adjusted. Accordingly, the distances between the target T and the magnet units 70a to 70q (the electromagnet part 70q2) are adjusted. Sputtering gas is introduced into the film formation space R from the gas supply part 60. The pressure in the film formation space R is adjusted to a predetermined pressure by controlling the pressure control valve. In this state, predetermined electric power is supplied to the target T from the sputtering power supply 30A electrically connected to the target T. Plasma is generated in the vacuum chamber 10, and sputtering becomes possible. At this time, predetermined electric power may be supplied to the substrate stage 20 from the bias power supply 30B. As long as desired plasma is ready to be generated in the vacuum chamber 10, the order of a plurality of process steps in the film formation preparing process may be appropriately adjusted.

The control device CONT determines currents to flow into the first electromagnet 71 and the second electromagnet 72 from the coil power supply 78.

The control device CONT controls the frequency of electric power from the coil power supply 78 using an inverter for each of the plurality of magnet units 70a to 70q (the electromagnet part 70q2) and supplies AC power with a phase difference.

In control of the control device CONT, the plurality of magnet units 70a to 70q (the electromagnet part 70q2) are grouped into three blocks which are substantially triadically symmetric. The control device CONT applies AC currents with phase differences of 120 degrees to the magnet units 70a to 70q (the electromagnet part 70q2) of the blocks. This block grouping is determined for each of the first magnet pattern P1 to the third magnet pattern P3.

That is, the control device CONT groups the magnet unit 70a, the magnet unit 70b, and the magnet unit 70c of the first magnet pattern P1 into three blocks which are substantially triadically symmetric. The control device CONT applies AC currents with phase differences of 120 degrees to the first electromagnets 71 of the magnet unit 70a, the magnet unit 70b, and the magnet unit 70c.

The control device CONT groups the magnet unit 70d, the magnet unit 70e, the magnet unit 70f, the magnet unit 70g, the magnet unit 70h, and the magnet unit 70i of the second magnet pattern P2 into three blocks which are substantially triadically symmetric. The control device CONT applies AC currents with phase differences of 120 degrees to the first electromagnets 71 of the magnet unit 70d, the magnet unit 70e, the magnet unit 70f, the magnet unit 70g, the magnet unit 70h, and the magnet unit 70i.

The control device CONT groups the magnet unit 70j, the magnet unit 70k, the magnet unit 70m, the magnet unit 70n, the magnet unit 70p, and the magnet unit 70q of the third magnet pattern P3 into three blocks which are substantially triadically symmetric. The control device CONT applies AC currents with phase differences of 120 degrees to the first electromagnets 71 of the magnet unit 70j, the magnet unit 70k, the magnet unit 70m, the magnet unit 70n, the magnet unit 70p, and the magnet unit 70q.

At this time, the frequency and the amplitude of the AC currents flowing into the first electromagnets 71 and the second electromagnets 72 can be changed.

Accordingly, the control device CONT rotates a leakage magnetic field generated by the plurality of electromagnets 72.

The control device CONT groups the plurality of magnet units 70a to 70q (the electromagnet part 70q2) into a plurality of groups which are substantially concentric. The control device CONT changes the amplitude of the AC power supplied to the electromagnets for each group. Accordingly, the control device CONT forms a film with a desired film formation profile on the substrate S. The plurality of magnet units 70a to 70q (the electromagnet part 70q2) are grouped into five groups in the example shown in FIG. 2, but the number of groups is not limited to the example shown in FIG. 2. When three-phase AC currents flow in the sputtering apparatus, the number of grouped blocks is a multiple of 3. By delaying the phase of a single-phase AC current, it is possible to realize a leakage magnetic field rotating with any number of blocks.

### <Waveform of Current Supplied to Magnet Unit>

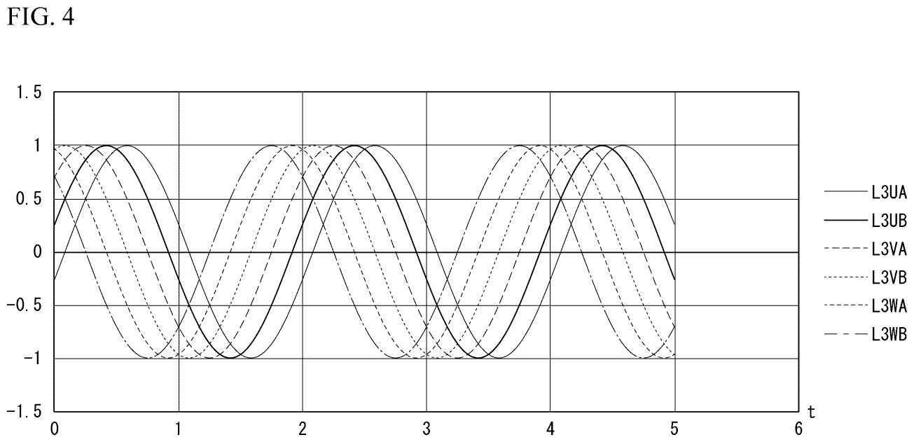

FIG. 4 is a graph showing an example of a current which is supplied from the coil power supply 78 to the first electromagnet 71 in the plasma processing apparatus according to the present embodiment.

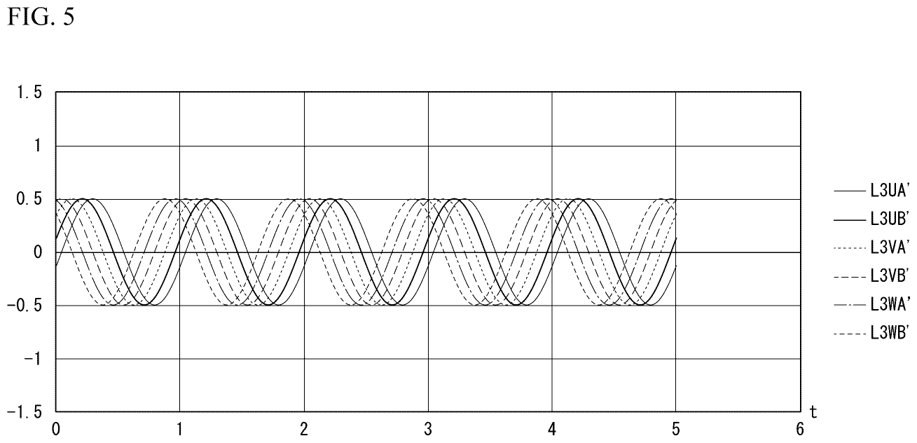

FIG. 5 is a graph showing an example of a current which is supplied from the coil power supply 78 to the second electromagnet 72 in the plasma processing apparatus according to the present embodiment.

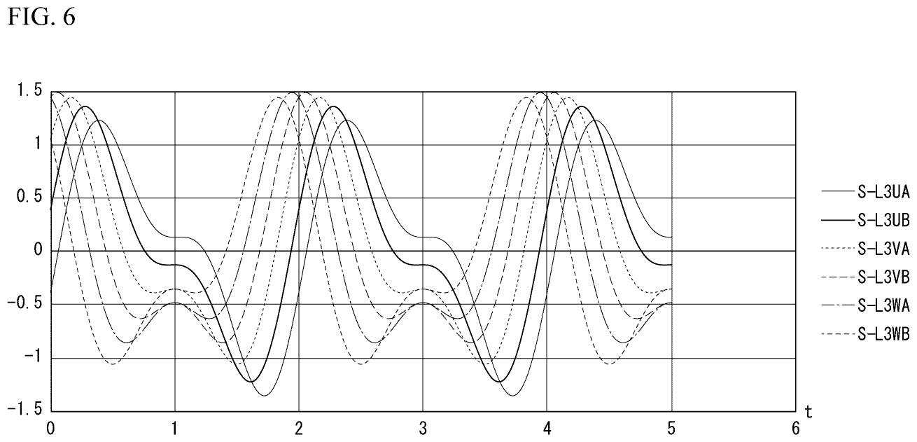

FIG. 6 is a graph showing an example of a current which is supplied from the coil power supply 78 to one magnet unit in the plasma processing apparatus according to the present embodiment.

In FIGS. 4 to 6, the horizontal axis represents a change of time [sec], and the vertical axis represents a current value [A]. FIGS. 4 and 5 show examples of the current value. In the present embodiment shown in FIGS. 4 and 5, a specific current value is not limited.

For example, the control device CONT causes a U-phase current of the three-phase AC currents to flow in the first electromagnets 71 of the magnet unit 70a, the magnet unit 70f, the magnet unit 70i, the magnet unit 70k, and the magnet unit 70p. The control device CONT causes a V-phase current of the three-phase AC currents to flow in the first electromagnets 71 of the magnet unit 70c, the magnet unit 70h, the magnet unit 70e, the magnet unit 70m, and the magnet unit 70q. The control device CONT causes a W-phase current of the three-phase AC currents to flow in the first electromagnets 71 of the magnet unit 70b, the magnet unit 70d, the magnet unit 70n, the magnet unit 70j, and the magnet unit 70n.

In addition, the control device CONT groups the magnet unit 70a, the magnet unit 70b, and the magnet unit 70c of the first magnet pattern P1 into three blocks which are substantially triadically symmetric. The control device CONT applies AC currents with phase differences of a predetermined degree to the first electromagnets 71 of the magnet unit 70a, the magnet unit 70b, and the magnet unit 70c.

The control device CONT groups the magnet unit 70d, the magnet unit 70e, the magnet unit 70f, the magnet unit 70g, the magnet unit 70h, and the magnet unit 70i of the second magnet pattern P2 into three blocks which are substantially triadically symmetric. The control device CONT applies AC currents with phase differences of a predetermined degree to the first electromagnets 71 of the magnet unit 70d, the magnet unit 70e, the magnet unit 70f, the magnet unit 70g, the magnet unit 70h, and the magnet unit 70i.

The control device CONT groups the magnet unit 70j, the magnet unit 70k, the magnet unit 70m, the magnet unit 70n, the magnet unit 70p, and the magnet unit 70q of the third magnet pattern P3 into three blocks which are substantially triadically symmetric. The control device CONT applies AC currents with phase differences of a predetermined degree to the first electromagnets 71 of the magnet unit 70j, the magnet unit 70k, the magnet unit 70m, the magnet unit 70n, the magnet unit 70p, and the magnet unit 70q.

For example, a U-phase current of the three-phase AC currents flows in the second electromagnets 72 of the magnet unit 70a, the magnet unit 70f, the magnet unit 70i, the magnet unit 70k, and the magnet unit 70p. A V-phase current of the three-phase AC currents flows in the second electromagnets 72 of the magnet unit 70c, the magnet unit 70h, the magnet unit 70e, the magnet unit 70m, and the magnet unit 70q. A W-phase current of the three-phase AC currents flows in the second electromagnets 72 of the magnet unit 70b, the magnet unit 70d, the magnet unit 70n, the magnet unit 70j, and the magnet unit 70n.

In addition, the control device CONT groups the magnet unit 70a, the magnet unit 70b, and the magnet unit 70c of the first magnet pattern P1 into three blocks which are substantially triadically symmetric. The control device CONT applies AC currents with phase differences of a predetermined degree to the second electromagnets 72 of the magnet unit 70a, the magnet unit 70b, and the magnet unit 70c.

The control device CONT groups the magnet unit 70d, the magnet unit 70e, the magnet unit 70f, the magnet unit 70g, the magnet unit 70h, and the magnet unit 70i of the second magnet pattern P2 into three blocks which are substantially triadically symmetric. The control device CONT applies AC currents with phase differences of a predetermined degree to the second electromagnets 72 of the magnet unit 70d, the magnet unit 70e, the magnet unit 70f, the magnet unit 70g, the magnet unit 70h, and the magnet unit 70i.

The control device CONT groups the magnet unit 70j, the magnet unit 70k, the magnet unit 70m, the magnet unit 70n, the magnet unit 70p, and the magnet unit 70q of the third magnet pattern P3 into three blocks which are substantially triadically symmetric. The control device CONT applies AC currents with phase differences of a predetermined degree to the second electromagnets 72 of the magnet unit 70j, the magnet unit 70k, the magnet unit 70m, the magnet unit 70n, the magnet unit 70p, and the magnet unit 70q.

Specifically, the control device CONT controls electric power supplied to the first electromagnets 71 of the plurality of magnet units 70a to 70q (the electromagnet part 70q2) as shown in FIG. 4.

The control device CONT groups the magnet unit 70a, the magnet unit 70b, and the magnet unit 70c of the first magnet pattern P1 into three blocks which are substantially triadically symmetric. The control device CONT causes a U-phase current L1U, a V-phase current L1V, and a W-phase current L1W of the three-phase AC currents to flow in the magnet units.

As shown in FIG. 2, the control device CONT causes the U-phase current L1U of the three-phase AC currents to flow in the first electromagnet 71 of the magnet unit 70a. The control device CONT causes the V-phase current L1V of the three-phase AC currents to flow in the first electromagnet 71 of the magnet unit 70b. The control device CONT causes the W-phase current L1W of the three-phase AC currents to flow in the first electromagnet 71 of the magnet unit 70c.

The control device CONT groups the magnet unit 70d, the magnet unit 70e, the magnet unit 70f, the magnet unit 70g, the magnet unit 70h, and the magnet unit 70i of the second magnet pattern P2 into three blocks which are substantially triadically symmetric. The control device CONT causes U-phase currents L2U1 and L2U2, V-phase currents L2V1 and L2V2, and W-phase currents L2W1 and L2W2 of the three-phase AC currents to flow in the magnet units.

As shown in FIG. 2, the control device CONT causes the W-phase current L2W2 of the three-phase AC currents to flow in the first electromagnet 71 of the magnet unit 70d. The control device CONT causes the V-phase current L2V2 of the three-phase AC currents to flow in the first electromagnet 71 of the magnet unit 70e. The control device CONT causes the U-phase current L2U2 of the three-phase AC currents to flow in the first electromagnet 71 of the magnet unit 70f. The control device CONT causes the W-phase current L2W1 of the three-phase AC currents to flow in the first electromagnet 71 of the magnet unit 70g. The control device CONT causes the V-phase current L2V1 of the three-phase AC currents to flow in the first electromagnet 71 of the magnet unit 70h. The control device CONT causes the U-phase current L2U1 of the three-phase AC currents to flow in the first electromagnet 71 of the magnet unit 70i.

The control device CONT groups the magnet unit 70j, the magnet unit 70k, the magnet unit 70m, the magnet unit 70n, the magnet unit 70p, and the magnet unit 70q of the third magnet pattern P3 into three blocks which are substantially triadically symmetric. The control device CONT causes U-phase currents L3U1-A, L3U1-B, L3U2-A, and L3U2-B, V-phase currents L3V1-A, L3V1-B, L3V2-A, and L3V2-B, and W-phase currents L3W1-A, L3W1-B, L3W2-A, and L3W2-B of the three-phase AC currents to flow in the magnet units as shown in FIG. 4.

As shown in FIG. 2, the control device CONT causes the W-phase current L3W2-A of the three-phase AC currents to flow in the first electromagnet 71 of the magnet unit 70j (the electromagnet part 70j1). The control device CONT causes the W-phase current L3W2-B of the three-phase AC currents to flow in the first electromagnet 71 of the magnet unit 70j (the electromagnet part 70j2). The control device CONT causes the U-phase current L3U1-A of the three-phase AC currents to flow in the first electromagnet 71 of the magnet unit 70k (the electromagnet part 70k1). The control device CONT causes the U-phase current L3U1-B of the three-phase AC currents to flow in the first electromagnet 71 of the magnet unit 70k (the electromagnet part 70k2).

The control device CONT causes the V-phase current L3V1-A of the three-phase AC currents to flow in the first electromagnet 71 of the magnet unit 70m (the electromagnet part 70m1). The control device CONT causes the V-phase current L3V1-B of the three-phase AC currents to flow in the first electromagnet 71 of the magnet unit 70m (the electromagnet part 70m2). The control device CONT causes the W-phase current L3W1-A of the three-phase AC currents to flow in the first electromagnet 71 of the magnet unit 70n (the electromagnet part 70n1). The control device CONT causes the W-phase current L3W1-B of the three-phase AC currents to flow in the first electromagnet 71 of the magnet unit 70n (the electromagnet part 70n2).

The control device CONT causes the U-phase current L3U2-A of the three-phase AC currents to flow in the first electromagnet 71 of the magnet unit 70p (the electromagnet part 70p1). The control device CONT causes the U-phase current L3U2-B of the three-phase AC currents to flow in the first electromagnet 71 of the magnet unit 70p (the electromagnet part 70p2). The control device CONT causes the V-phase current L3V2-A of the three-phase AC currents to flow in the first electromagnet 71 of the magnet unit 70q (the electromagnet part 70q1). The control device CONT causes the V-phase current L3V2-B of the three-phase AC currents to flow in the first electromagnet 71 of the magnet unit 70q (the electromagnet part 70q2).

The control device CONT controls electric power supplied to the second electromagnets 72 of the plurality of magnet units 70a to 70q (the electromagnet part 70q2) as shown in FIG. 5.

The control device CONT groups the magnet unit 70j, the magnet unit 70k, the magnet unit 70m, the magnet unit 70n, the magnet unit 70p, and the magnet unit 70q of the third magnet pattern P3 into three blocks which are substantially triadically symmetric. The control device CONT causes U-phase currents L3U1A′, L3UTB′, L3U2A′, and L3U2B′, V-phase currents L3V1A′, L3V1B′, L3V2A′, and L3V2B′, and W-phase currents L3W1A′, L3W1B′, L3W2A′, and L3W2B′ of the three-phase AC currents to flow in the magnet units as shown in FIG. 5.

As shown in FIG. 2, the control device CONT causes the W-phase current L3W2A′ of the three-phase AC currents to flow in the second electromagnet 72 of the magnet unit 70j (the electromagnet part 70j1). The control device CONT causes the W-phase current L3W2B′ of the three-phase AC currents to flow in the second electromagnet 72 of the magnet unit 70j (the electromagnet part 70j2). The control device CONT causes the U-phase current L3U1A′ of the three-phase AC currents to flow in the first electromagnet 71 of the magnet unit 70k (the electromagnet part 70k1). The control device CONT causes the U-phase current L3U1B′ of the three-phase AC currents to flow in the second electromagnet 72 of the magnet unit 70k (the electromagnet part 70k2).

The control device CONT causes the V-phase current L3V1A′ of the three-phase AC currents to flow in the second electromagnet 72 of the magnet unit 70m (the electromagnet part 70m1). The control device CONT causes the V-phase current L3V1B′ of the three-phase AC currents to flow in the second electromagnet 72 of the magnet unit 70m (the electromagnet part 70m2). The control device CONT causes the W-phase current L3W1A′ of the three-phase AC currents to flow in the second electromagnet 72 of the magnet unit 70n (the electromagnet part 70n1). The control device CONT causes the W-phase current L3W1B′ of the three-phase AC currents to flow in the second electromagnet 72 of the magnet unit 70n (the electromagnet part 70n2).

The control device CONT causes the U-phase current L3U2A′ of the three-phase AC currents to flow in the second electromagnet 72 of the magnet unit 70p (the electromagnet part 70p1). The control device CONT causes the U-phase current L3U2B′ of the three-phase AC currents to flow in the second electromagnet 72 of the magnet unit 70p (the electromagnet part 70p2). The control device CONT causes the V-phase current L3V2A′ of the three-phase AC currents to flow in the second electromagnet 72 of the magnet unit 70q (the electromagnet part 70q1). The control device CONT causes the V-phase current L3V2B′ of the three-phase AC currents to flow in the second electromagnet 72 of the magnet unit 70q (the electromagnet part 70q2).

FIG. 6 shows current waveforms obtained by superimposing the current waveforms shown in FIG. 4 and the current waveforms shown in FIG. 5. In other words, the current waveforms shown in FIG. 6 indicate currents supplied to the magnet units when each of the plurality of magnet units 70a to 70q (the electromagnet part 70q2) includes one electromagnet (one coil part).

By using the current waveforms shown in FIG. 6, the same magnetic field as when two electromagnets are used can be generated in the magnet unit including one coil part without using two electromagnets (the first electromagnet 71 and the second electromagnet 72).

In FIGS. 4 to 6, reference signs L3UA, L3VA, and L3WA are not shown in the drawings. In this case, L3UA, L3VA, and L3WA indicate a U-phase current of the three-phase AC currents flowing in the third magnet pattern P3, a V-phase current of the three-phase AC currents, and a W-phase current of the three-phase AC currents. Similarly, L3UA, L3VA, L3WA, L3UB, L3VB, L3WB, L3UA′, L3VA′, L3WA′, L3UB′, L3VB′, and L3WB′ correspond to the phases of the supplied AC currents in the magnet units 70j to 70q shown in FIG. 2.

Here, the AC currents are supplied to the magnet units from the coil power supply 78. FIGS. 4 and 5 show cases in which currents with a simple sinusoidal waveform are supplied to the magnet units from the coil power supply 78. On the other hand, FIG. 6 shows current waveforms with more complicated waveforms than those shown in FIGS. 4 and 5.

In the plasma processing apparatus 100 according to the present embodiment, currents of the simple sinusoidal waveforms shown in FIGS. 4 and 5 may be supplied from the coil power supply 78 to the first electromagnets 71 and the second electromagnets 72 without using currents of complicated waveforms shown in FIG. 6. Accordingly, it is possible to easily control the currents supplied from the coil power supply 78 to the first electromagnets 71 and the second electromagnets 72 and to obtain excellent processing characteristics such as to form a film with a desired profile on the substrate S.

Accordingly, even when a film formation distribution excellent in uniformity such as less than ±3% is required as a distribution of film formation characteristics obtained by the plasma processing apparatus 100, it is possible to easily obtain a distribution excellent in uniformity. Particularly, it is possible to realize uniformity in film formation characteristics such as a film thickness in the radial direction of a substrate S for a circular substrate S.

Conventionally, much labor or time is required for this minute adjustment. According to the present embodiment, much labor or time is not required for minute adjustment. Accordingly, much time is not required for setting control conditions, electric power supplied to the magnet units does not need to be precisely controlled, and thus it is possible to contribute to improvement in productivity of the plasma processing apparatus 100.

It is possible to form a film with a desired film formation profile on a substrate S without checking whether non-erosion of a target T occurs. Accordingly, it is possible to easily suppress vibration from the target T due to non-erosion.

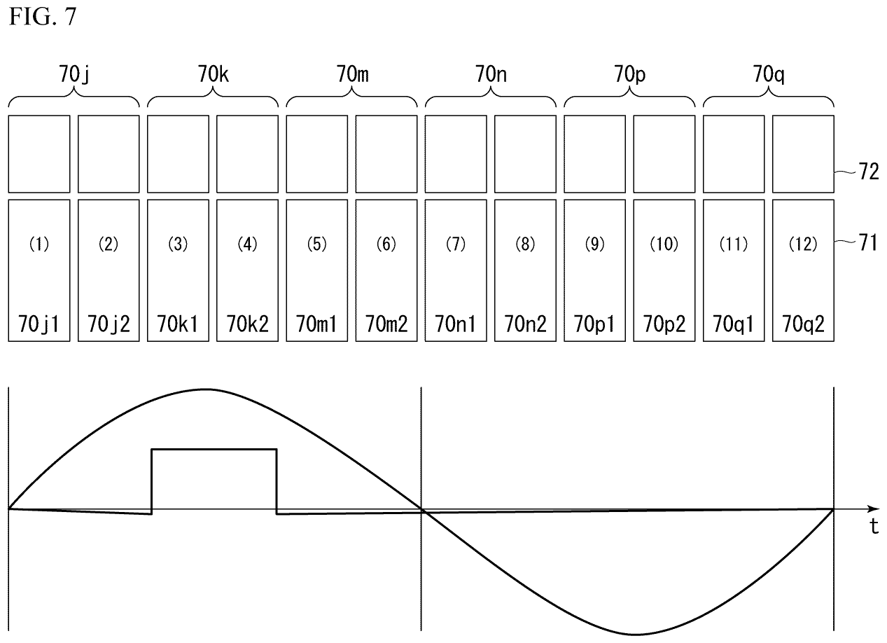

FIG. 7 is a diagram schematically showing an example of control in the plasma processing apparatus according to the present embodiment.

For example, when it is intended to increase a film thickness in an area on a substrate S corresponding to the magnet unit 70k as shown in FIG. 7, control for increasing a current supplied to the second electromagnet 72 of the magnet unit 70k can be performed. In this case, a configuration in which the second electromagnet 72 is provided in only the magnet unit 70k, the second electromagnet 72 is not provided in the other magnet units, and only the first electromagnet 71 is provided in the other magnet units may be employed. In this way, a configuration in which only the magnet unit located at a predetermined position includes double coils can be employed. The lower part of FIG. 7 shows a current waveform supplied from the coil power supply 78. In the current waveform shown in FIG. 7, the horizontal axis represents a time change [sec], and the vertical axis represents a current value [A].

### Second Embodiment

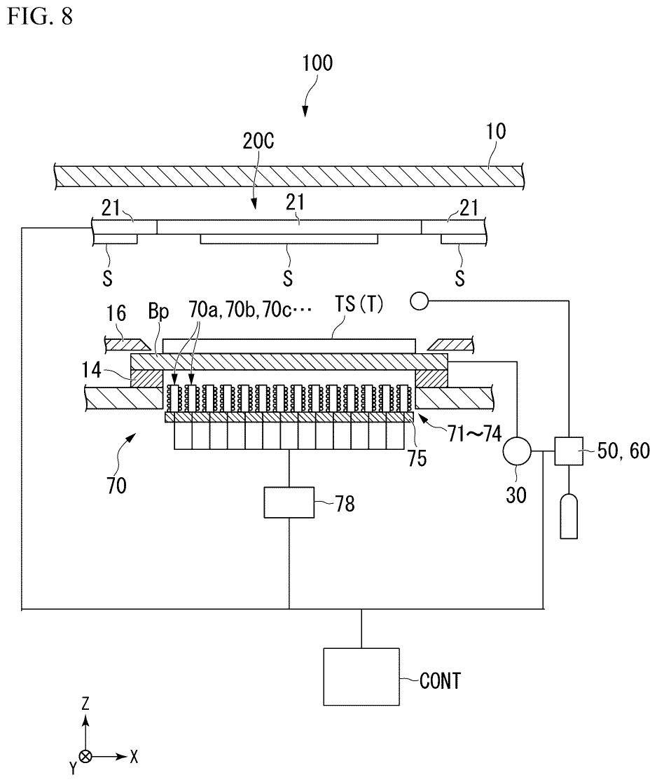

A plasma processing apparatus according to a second embodiment of the invention will be described below with reference to the drawings. FIG. 8 is a cross-sectional view showing the plasma processing apparatus according to the present embodiment. The present embodiment is different from the first embodiment in a sputtering system. In the second embodiment, the same constituents as in the first embodiment will be referred to by the same reference signs, and description thereof will be omitted or simplified.

The plasma processing apparatus 100 according to the present embodiment is a film-formation apparatus that forms a predetermined thin film on a rectangular substrate S such as a glass substrate. The plasma processing apparatus 100 according to the first embodiment is a film-formation apparatus based on a sputtering-down system, but a film-formation apparatus having a sputtering-up system will be described in the present embodiment. In the following description, the substrate S is a to-be-processed substrate which has a longitudinal rectangular shape in a carrying direction of the substrate S.

The plasma processing apparatus 100 according to the present embodiment includes a vacuum chamber 10 as shown in FIG. 8. A vacuum pump 50 constituted by a turbo-molecular pump or a rotary pump which is not particularly shown in the drawings is connected to the vacuum chamber 10. The vacuum pump 50 is configured to depressurize the inside of the vacuum chamber 10 to a predetermined pressure. A gas-introduction part is provided in the vacuum chamber 10. A gas introduction pipe and a gas supply mechanism for introducing rare gas such as argon or a reactant gas (sputtering gas) such as oxygen according to necessity via a mass flow controller are connected to the gas-introduction part. The gas supply mechanism is configured to introduce sputtering gas of which a flow rate has been controlled into the vacuum chamber 10. A substrate carrying mechanism 20C (a substrate support part) is provided in an upper space of the vacuum chamber 10. The substrate carrying mechanism 20C includes a carrier 21 in which a substrate S is set. The substrate carrying mechanism 20C can sequentially carry substrates S (from left to right in FIG. 8) to a position facing a target T which will be described later by intermittently driving a drive device which is not shown in the drawings. The substrate carrying mechanism 20C has a known structure. A sputtering cathode 70 is provided in a lower space of the vacuum chamber 10.

The sputtering cathode 70 has a shape corresponding to the substrate S. The sputtering cathode 70 includes a target T and a plurality of electromagnets 71 and 72. The target T has a larger area than that of the substrate S. The plurality of electromagnets 71 and 72 are arranged on a bottom side of the target T (the side of the target T opposite to a sputtering surface TS which is a top surface). The plurality of electromagnets 71 and 72 apply a leakage magnetic field into a film formation space facing the sputtering surface TS. The electromagnets 71 and 72 constitute magnet units 70a to 70q. The target T is selected according to a composition of a thin film to be formed on the bottom surface of the substrate S such as Al, an Al alloy, or Ti. A backing plate Bp is attached to the bottom surface of the target T. Regarding the target T, the target T can be cooled by causing a coolant to circulate in the backing plate Bp at the time of sputtering of the target T. The target T is provided in the vacuum chamber 10 via an insulating plate 14 such that the sputtering surface TS of the target T is opposite to the substrate S.

A sputtering power supply 30A such as a DC power supply or an AC power supply is connected to the target T. Electric power output from the sputtering power supply 30A is supplied to the target T. DC power of a negative potential or AC power of a predetermined frequency can be supplied to the target T according to a type of the target T. A ring-shaped shield plate 16 is provided in the vacuum chamber 10 such that the target T is surrounded thereby. The shield plate 16 is formed of a metal. The shield plate 16 is grounded. The shield plate 16 serves as an anode at the time of sputtering of the target T.

The sputtering cathode 70 includes a plate-shaped support member 75. The support member 75 has an area larger than or equal to that of the target T. The support member 75 is provided in parallel to the sputtering surface TS. The plurality of electromagnets 71 and 72 are provided in the support member 75. In each of the plurality of electromagnets 71 and 72, a coil part is wound around a magnetic core. A winding number of a coil and a position of a coil in the coil part are appropriately set. The magnetic core of each of the electromagnets 71 and 72 has a cylindrical shape with the same diameter. In this case, intervals between the magnetic cores of the electromagnets 71 and 72 in the radial direction and the circumferential direction of the sputtering surface TS in a plan view are substantially the same as in the first embodiment. The electromagnets 71 and 72 are arranged along the surface of the support member 75. The coil power supply 78 is connected to each of the electromagnets 71 and 72.

In the present embodiment, a plurality of magnet units 70a to 70q (an electromagnet part 70q2) are configured to generate a rectangular magnetic field corresponding to the rectangular substrate S, that is, a rectangular magnetic field similar to the sputtering surface TS. Each of first to third magnet patterns P1 to P3 has a rectangular shape similar to the sputtering surface TS to correspond to the rectangular substrate S. Accordingly, it is possible to oscillate a leakage magnetic field or to rotate a leakage magnetic field.

In the present embodiment, similarly to the first embodiment, operations of various members, devices, and mechanisms constituting the plasma processing apparatus 100 are controlled by a control device CONT.

### Third Embodiment

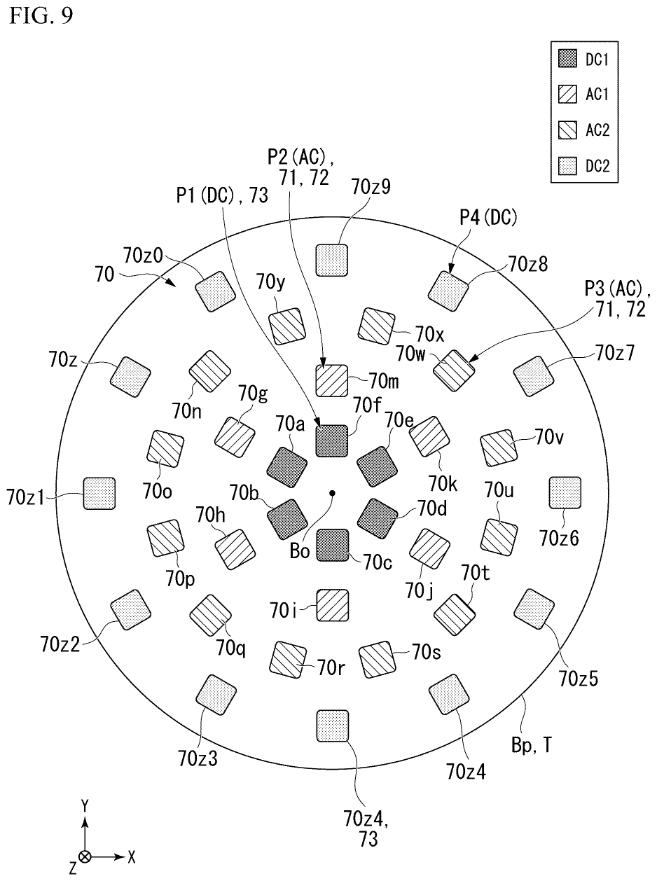

A plasma processing apparatus according to a third embodiment of the invention will be described below with reference to the drawings. FIG. 9 is a plan view schematically showing an arrangement of magnet units in the plasma processing apparatus according to the present embodiment. The present embodiment is different from the first embodiment in an arrangement of magnet units. In the third embodiment, the same constituents as in the first embodiment will be referred to by the same reference signs, and description thereof will be omitted or simplified.

In the plasma processing apparatus 100 according to the present embodiment, four-turn magnet patterns are arranged in a sputtering cathode 70 as an arrangement of the magnet units in the sputtering cathode 70. That is, the plasma processing apparatus 100 includes a first magnet pattern P1, a second magnet pattern P2, a third magnet pattern P3, and a fourth magnet pattern P4.

The first magnet pattern P1, the second magnet pattern P2, the third magnet pattern P3, and the fourth magnet pattern P4 are arranged to be concentric around the center axis Bo of the backing plate Bp.

The first magnet pattern P1 is circumferentially disposed to be closest to the center axis Bo. As shown in FIG. 9, in the first magnet pattern P1, a magnet unit 70a, a magnet unit 70b, a magnet unit 70c, a magnet unit 70d, a magnet unit 70e, and a magnet unit 70f are arranged in parallel in a ring shape.

The second magnet pattern P2 is circumferentially disposed at positions outside of the first magnet pattern P1 in the radial direction from the center axis Bo. As shown in FIG. 9, in the second magnet pattern P2, a magnet unit 70g, a magnet unit 70h, a magnet unit 70i, a magnet unit 70j, a magnet unit 70k, and a magnet unit 70m are arranged in parallel in a ring shape.

The third magnet pattern P3 is circumferentially disposed at positions outside of the second magnet pattern P2 in the radial direction from the center axis Bo. As shown in FIG. 9, in the third magnet pattern P3, a magnet unit 70n, a magnet unit 70o, a magnet unit 70p, a magnet unit 70q, a magnet unit 70r, a magnet unit 70s, a magnet unit 70t, a magnet unit 70u, a magnet unit 70v, a magnet unit 70w, a magnet unit 70x, and a magnet unit 70y are arranged in parallel in a ring shape.

The fourth magnet pattern P4 is circumferentially disposed at the outermost position in the radial direction from the center axis Bo. As shown in FIG. 9, in the fourth magnet pattern P4, a magnet unit 70z, a magnet unit 70z1, a magnet unit 70z2, a magnet unit 70z3, a magnet unit 70z4, a magnet unit 70z5, a magnet unit 70z6, a magnet unit 70z7, a magnet unit 70z8, a magnet unit 70z9, and a magnet unit 70z0 are arranged in parallel in a ring shape.

In the plasma processing apparatus 100 according to the present embodiment, the fourth magnet pattern P4 located at the outermost circumference and the first magnet pattern P1 located at the innermost circumference are in a direct current (DC) phase. That is, the polarities of the fourth magnet pattern P4 and the first magnet pattern P1 are fixed. The second magnet pattern P2 and the third magnet pattern P3 located between the fourth magnet pattern P4 and the first magnet pattern P1 in the radial direction are inverter-controlled. Accordingly, the sputtering cathode 70 is configured to generate a locked magnetic field.

In the present embodiment, in each of the second magnet pattern P2 and the third magnet pattern P3 in which inverter control using an AC current is performed, each magnet unit constituting the second magnet pattern P2 and the third magnet pattern P3 includes a first electromagnet 71 and a second electromagnet 72.

The control device CONT can control the frequency, the amplitude, and the phase in the first electromagnet 71 and the second electromagnet 72 in each of the magnet pattern P2 and the third magnet pattern P3.

In the magnet units of the fourth magnet pattern P4 located at the outermost circumference and the magnet units of the first magnet pattern P1 located at the innermost circumference, a permanent magnet can be used instead of an electromagnet of a DC phase.

In the magnet units of the fourth magnet pattern P4 located at the outermost circumference and the magnet units of the first magnet pattern P1 located at the innermost circumference, a configuration in which an electromagnet of a DC phase and a permanent magnet are combined may be used.

### Fourth Embodiment

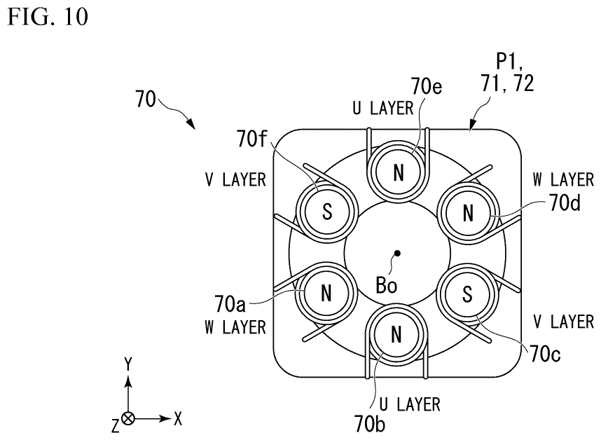

A plasma processing apparatus according to a fourth embodiment of the invention will be described below with reference to the drawings. FIG. 10 is a plan view schematically showing an arrangement of magnet units in the plasma processing apparatus according to the present embodiment. The present embodiment is different from the first embodiment in an arrangement of magnet units. In the fourth embodiment, the same constituents as in the first embodiment will be referred to by the same reference signs, and description thereof will be omitted or simplified.

In the plasma processing apparatus 100 according to the present embodiment, a one-turn magnet pattern is arranged in a sputtering cathode 70 as an arrangement of magnet units in the sputtering cathode 70. That is, the plasma processing apparatus 100 includes a first magnet pattern P1.

The first magnet pattern P1 is circumferentially arranged around the center axis Bo. As shown in FIG. 10, in the first magnet pattern P1, a magnet unit 70a, a magnet unit 70b, a magnet unit 70c, a magnet unit 70d, a magnet unit 70e, and a magnet unit 70f are arranged in parallel in a ring shape.

The control device CONT groups the magnet units 70a to 70f of the first magnet pattern P1 into three blocks which are substantially triadically symmetric. The control device CONT causes a W-phase current of three-phase AC currents to flow in the magnet unit 70a and the magnet unit 70d. The control device CONT causes a U-phase current of the three-phase AC currents to flow in the magnet unit 70b and the magnet unit 70e.

The control device CONT causes a V-phase current of the three-phase AC currents to flow in the magnet unit 70c and the magnet unit 70f. Coils of coil parts constituting the magnet unit 70c and the magnet unit 70f are wound in the reverse direction of the coils of the coil parts constituting the magnet unit 70a, the magnet unit 70b, the magnet unit 70d, and the magnet unit 70e.

Accordingly, it is possible to rotate a leakage magnetic field using a magnetic circuit of the first magnet pattern P1 and to generate plasma.

Each of the magnet units 70a to 70f includes a first electromagnet 71 and a second electromagnet 72. In this case, the frequency, the amplitude, and the phase of an AC current supplied to the first electromagnet 71 and an AC current supplied to the second electromagnet 72 are controlled.

### Fifth Embodiment

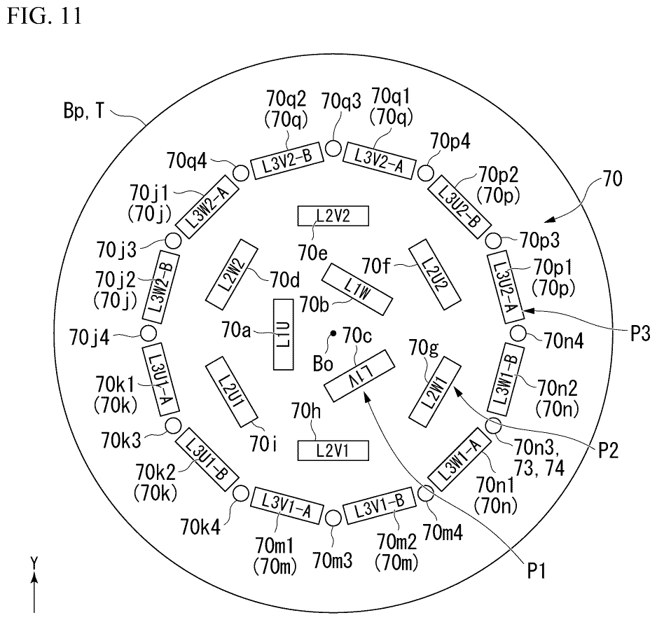

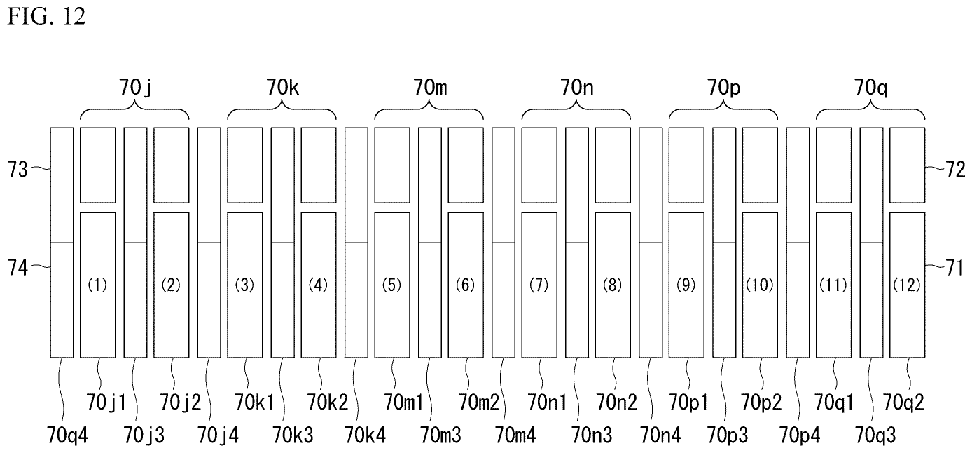

A plasma processing apparatus according to a fifth embodiment of the invention will be described below with reference to the drawings. FIG. 11 is a plan view schematically showing an arrangement of magnet units in a sputtering cathode of the plasma processing apparatus according to the present embodiment. FIG. 12 is a diagram schematically showing an example of control in a magnet pattern at an outermost circumference. The present embodiment is different from the first embodiment in an arrangement of magnet units. In the fifth embodiment, the same constituents as in the first embodiment will be referred to by the same reference signs, and description thereof will be omitted or simplified.

Regarding a configuration of the magnet units according to the present embodiment, the arrangement in a plan view shown in FIG. 2 according to the first embodiment corresponds to FIG. 11. The example of control shown in FIG. 7 according to the first embodiment corresponds to FIG. 12.

In the present embodiment, each of the magnet units 70j to 70q includes electromagnets 71, 72, and 73. Each of the electromagnets 71, 72, and 73 has a configuration in which a plurality of coils generating a magnetic field in the Z direction are combined. Each of the magnet units 70j to 70q includes a permanent magnet 74 generating a magnetic field in the Z direction.

Here, the magnet unit 70j will be described. In the third magnet pattern P3 located at the outermost circumference, the magnet unit 70j includes an interposed magnet part 70j3 and an interposed magnet part 70j4 in addition to an electromagnet part 70j1 and an electromagnet part 70j2.

Each of the electromagnet part 70j1 and the electromagnet part 70j2 includes a first electromagnet 71 and a second electromagnet 72.

The interposed magnet part 70j3 and the interposed magnet part 70j4 are arranged to be adjacent to the electromagnet part 70j1 and the electromagnet part 70j2 on the line of the ring-shape third magnet pattern P3. That is, in the magnet unit 70j, the interposed magnet part 70j4, the electromagnet part 70j2, the interposed magnet part 70j3, and the electromagnet part 70j1 are sequentially arranged in parallel in the circumferential direction of the third magnet pattern P3.

The interposed magnet part 70j3 and the interposed magnet part 70j4 have the same configuration.

In each of the interposed magnet part 70j3 and the interposed magnet part 70j4, a third electromagnet (electromagnet) 73 and a permanent magnet 74 are superimposed in the Z direction. The third electromagnet 73 and the permanent magnet 74 are arranged to be coaxial with each other. Each of the interposed magnet part 70j3 and the interposed magnet part 70j4 may include only the third electromagnet 73. Alternatively, each of the interposed magnet part 70j3 and the interposed magnet part 70j4 may include only the permanent magnet 74. Alternatively, one of the interposed magnet part 70j3 and the interposed magnet part 70j4 may include the third electromagnet 73 and the other may include the permanent magnet 74.

Similarly to the first electromagnet 71 and the second electromagnet 72, the third electromagnet 73 is connected to the coil power supply 78. In the third electromagnet 73, magnetic field generation power supplied by the control device CONT is controlled. In the present embodiment, the third electromagnet 73 is supplied with a DC current.

Similarly to the magnet unit 70j, the magnet units 70k to 70q have a configuration in which four magnet parts are arranged to be adjacent to each other. In the magnet units 70j to 70q, the magnet parts are in contact with or adjacent to each other. Specifically, as long as the magnetic field in the Z direction generate in the third magnet pattern P3 is not distorted in a direction crossing the center axis Bo, the magnet parts may be in contact with each other or may be separated to be adjacent to each other.

Combinations of the first electromagnet 71, the second electromagnet 72, and the interposed magnet parts in the magnet units 70a, 70b, 70c, . . . are shown in Table 1. Here, the interposed magnet part includes only the permanent magnet 74, but a configuration in which the interposed magnet parts include the third electromagnet 73 may be employed.

TABLE 1

| First magnet, second magnet | First magnet | Second magnet | Interposed magnet part |
|---|---|---|---|
| Only permanent magnet | — | — | Permanent magnet |
| Not dividied | Electromagnet (AC) | — | — |
| (single winding) | Electromagnet (DC) | — | — |
| Permanent magnet | Electromagnet (AC) | — | Permanent magnet |
| hybrid | Electromagnet (DC) | — | Permanent magnet |
| Double winding | Electromagnet (AC) | Electromagnet (AC) | — |
| | Electromagnet (DC) | Electromagnet (AC) | — |
| | Electromagnet (DC) | Electromagnet (DC) | — |
| Double winding | Electromagnet (AC) | Electromagnet (AC) | Permanent magnet |
| hybrid | Electromagnet (DC) | Electromagnet (AC) | Permanent magnet |
| | ELECTROMAGNET (DC) | Electromagnet (DC) | Permanent magnet |

According to the present embodiment, in the electromagnet parts 70j1 to 70q2, a configuration in which the electromagnets 71 and 72 supplied with an AC current are combined is used. Accordingly, it is possible to adjust a magnetic field at a specific position. In the interposed magnet parts 70j3 to 70q4, a configuration in which the electromagnet 73 and the permanent magnet 74 supplied with a DC current are combined is used. Accordingly, it is possible to decrease an amount of current flowing in the electromagnet 73 and to contribute to a decrease in power consumption.

In the present embodiment, the individual configurations according to the aforementioned embodiments can be selected and combined for implementation.

### EXAMPLES

Examples of the invention will be described below.

Check tests performed on the plasma processing apparatus will be described below as specific examples of the plasma processing apparatus according to the invention.

### Experimental Example 1

The sputtering cathode shown in FIG. 2 was used, and electric power was supplied to only the first electromagnet 71 to generate a magnetic field. At this time, in the magnet units 70a to 70q, electric power was supplied to only the first electromagnet 71. Electric power of the sinusoidal waveform shown in FIG. 4 was supplied to the first electromagnets 71 of the magnet units 70a to 70q.

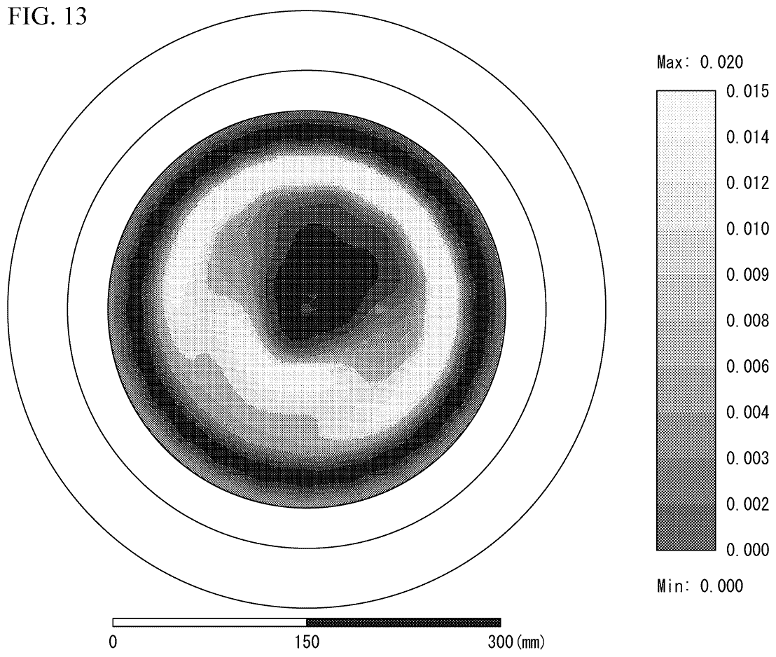

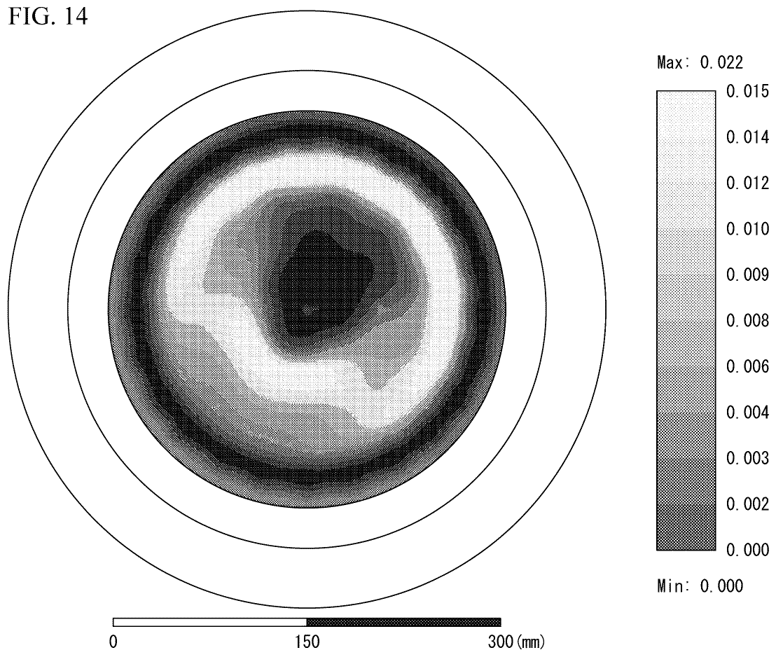

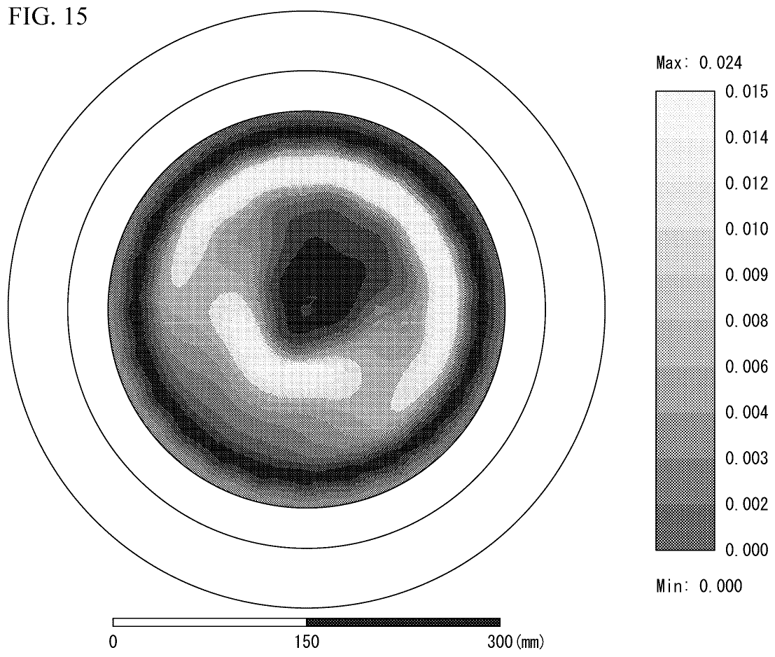

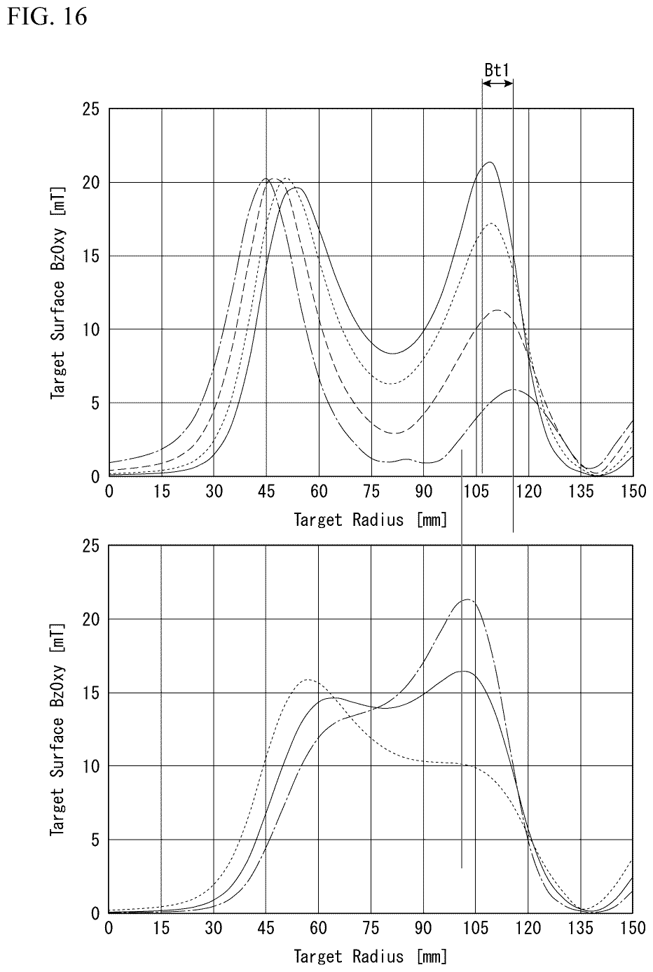

The magnetic field generated through this control is shown in FIGS. 13 to 15. An average magnetic field intensity in the radial direction of the generated magnetic field is shown in FIG. 16.

FIGS. 13 to 15 show a spatial distribution at different times of a rotating magnetic field generated by the magnet units 70a to 70q.

### Experimental Example 2

Then, the sputtering cathode shown in FIG. 2 was used, and electric power was supplied to the second electromagnet 72 in addition to the first electromagnet 71 to generate a magnetic field. At this time, in the magnet units 70a to 70q, electric power was supplied to the second electromagnet 72 in addition to the first electromagnet 71.

Electric power of the sinusoidal waveform shown in FIG. 4 was supplied to the first electromagnets 71 of the magnet units 70a to 70q. Electric power of the sinusoidal waveform shown in FIG. 5 was supplied to the second electromagnets 72 of the magnet units 70a to 70q.

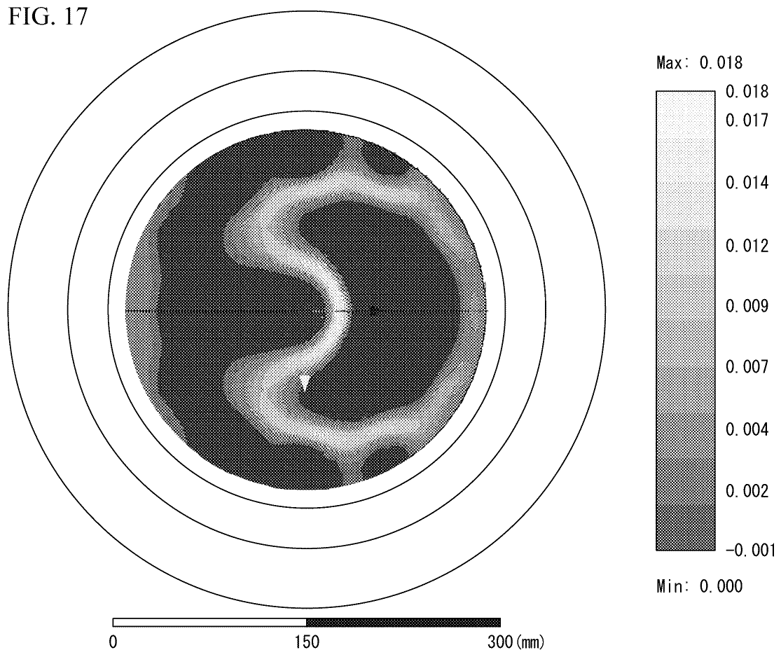

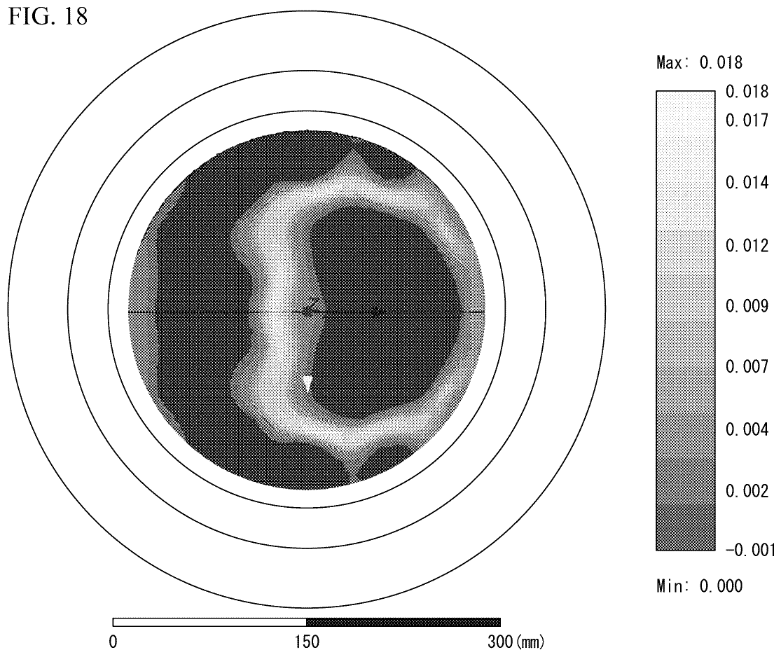

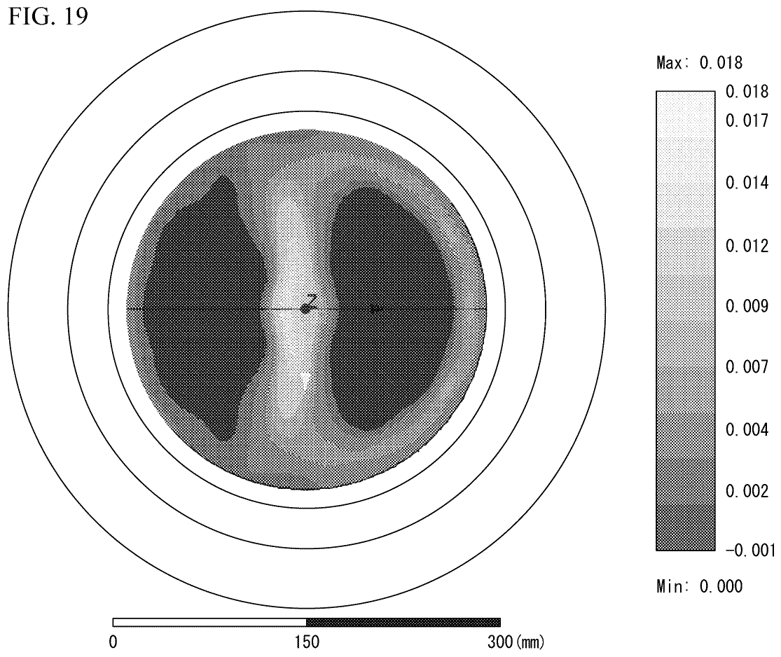

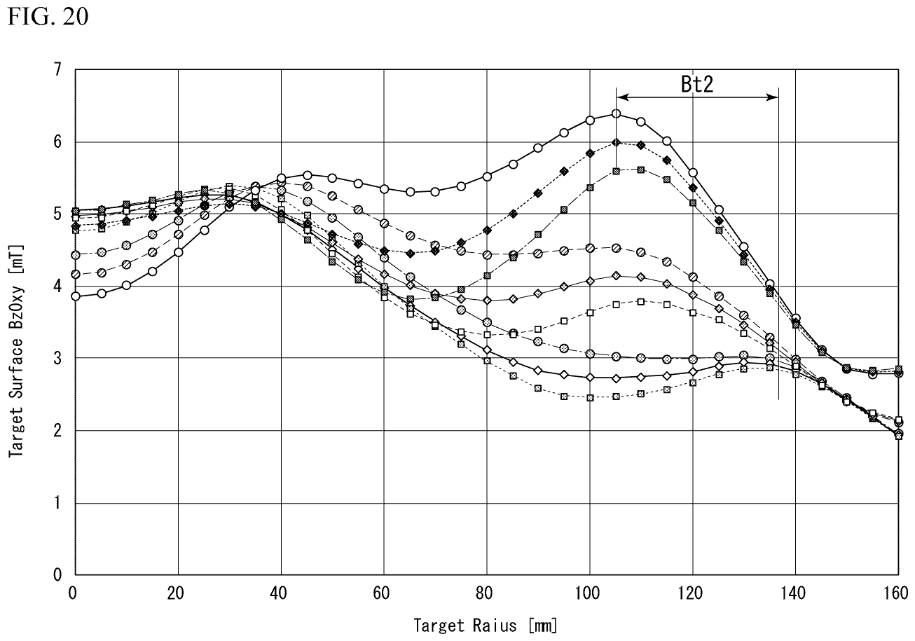

The magnetic field generated through this control is shown in FIGS. 17 to 19. An average magnetic field intensity in the radial direction of the generated magnetic field is shown in FIG. 20.

FIGS. 17 to 19 show a spatial distribution at different times of a rotating magnetic field generated by the magnet units 70a to 70q.

From these results, in the magnetic field generated by supplying electric power to only the first electromagnet 71, a peak magnetic field near the outer circumference of the first electromagnet 71 can move in only a range of a distance Bt1 in the radial direction as shown in FIG. 16. On the other hand, in the magnetic field generated by supplying electric power to the second electromagnet 72 in addition to the first electromagnet 71, it can be seen that a peak magnetic field near the outer circumference of the first electromagnet 71 and the second electromagnet 72 can move in a range of a distance Bt2 in the radial direction as shown in FIG. 20. Accordingly, it can be seen that a planar magnetic field distribution can be greatly changed in the magnetic field shown in FIGS. 17 to 19.

### Experimental Example 3

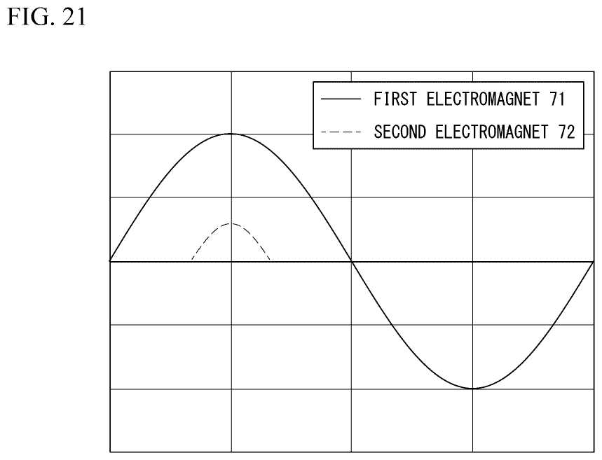

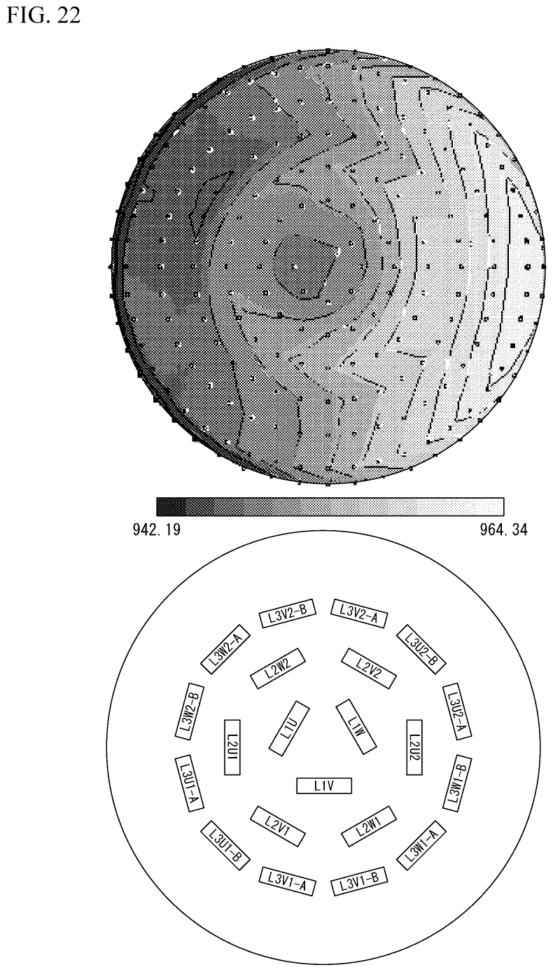

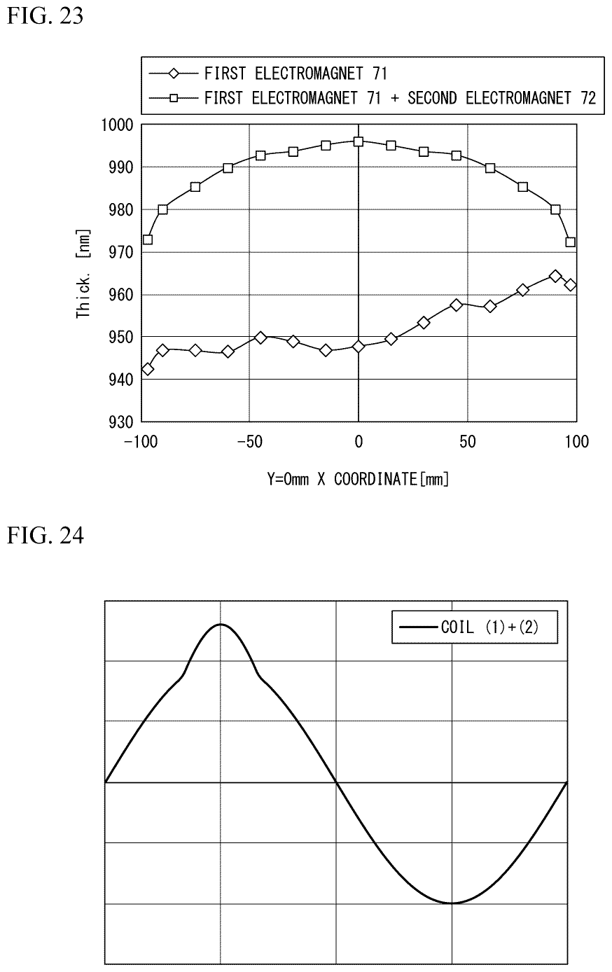

First, electric power of a sinusoidal wave shown in FIG. 21 was supplied to only the first electromagnet 71 to generate a magnetic field, and film formation was performed using the plasma processing apparatus 100. A film thickness distribution obtained at that time is shown in FIGS. 22 and 23. As shown in FIGS. 22 and 23, it can be seen that the film thickness in the left part of the drawings was smaller.

Specifications of the sputtering cathode are as follows.
Diameter: 300 mm
Electric power of first electromagnet 71: three phases and two poles
Frequency: 1 Hz
Electric power of second electromagnet 72: three phases and six poles
Frequency: 1 Hz
Material of target: Al
Target film thickness: 1000 nm

### Experimental Example 4

Similarly, electric power of a sinusoidal wave shown in FIG. 21 was supplied to the first electromagnet 71 to generate a magnetic field, electric power of a sinusoidal wave shown in FIG. 21 was supplied to the second electromagnet 72 to generate a magnetic field, and film formation was performed using the plasma processing apparatus 100. A film thickness distribution obtained at that time is shown in FIG. 23. As shown in FIG. 23, it can be seen that the film thickness distribution was uniformized.

As shown in FIG. 24, it can be seen that film formation using the plasma processing apparatus 100 was able to be realized by supplying electric power of a combined sinusoidal waveform to a single coil part to generate a magnetic field.

While preferred embodiments and modified examples of the invention have been described and shown above, it should be understood that these are exemplary of the invention and are not to be considered as limiting. Additions, omissions, substitutions, and other modifications can be made without departing from the scope of the invention. Accordingly, the invention is not to be considered as being limited by the foregoing description.

### REFERENCE SIGNS LIST

10 . . . Vacuum chamber
11 . . . Lower chamber
12 . . . Upper chamber
12A . . . Opening
12S . . . Sealing member
14 . . . Insulating plate
16 . . . Shield plate
20 . . . Substrate stage
20a . . . Substrate mounting surface
20A . . . T/S changing mechanism
20C . . . Substrate carrying mechanism
21 . . . Carrier
30A . . . Sputtering power supply
30B . . . Bias power supply
50 . . . Vacuum pump
60 . . . Gas supply part
70 . . . Sputtering cathode
70a, 70b, 70c, 70d, 70e, 70f, 70g, 70h, 70i, 70j, 70k, 701, 70m, 70n, 70o, 70p, 70q, 70r,
70s, 70t, 70u, 70v, 70w, 70x, 70y, 70z, 70z0, 70z1, 70z2, 70z3 . . . , 70z4, 70z5, 70z6, 70z7,
70z8, 70z9 . . . Magnet unit
70j1, 70j2, 70k1, 70k2, 70m1, 70m2, 70n1, 70n2, 70p1, 70p2, 70q1, 70q2 . . . Electromagnet part
70j3, 70j4, 70q4 . . . Interposed magnet part
70SP, 75 . . . Support member
71 . . . First electromagnet (electromagnet)
72 . . . Second electromagnet (electromagnet)
73 . . . Third electromagnet (electromagnet)
74 . . . Magnet (permanent magnet)
78 . . . Coil power supply
80 . . . Heater
80A . . . Heater power supply
90 . . . Cooling mechanism
91 . . . Cooling pipe
92 . . . Coolant supply part
100 . . . Plasma processing apparatus
Ba . . . Bottom surface
Bb . . . Top surface
Bo . . . Center axis
Bp . . . Backing plate
C1 . . . First coil part (coil part)
C2 . . . Second coil part (coil part)
CONT . . . Control device
MC . . . Magnetic core
MC1 . . . First magnetic core
MC2 . . . Second magnetic core
P1 . . . First magnet pattern (magnet pattern)
P2 . . . Second magnet pattern (magnet pattern)
P3 . . . Third magnet pattern (magnet pattern)
P4 . . . Fourth magnet pattern (magnet pattern)
R . . . Film formation space
S . . . Substrate
T . . . Target
TS . . . Sputtering surface

What is claimed is:

1. A plasma processing apparatus comprising:
a vacuum chamber having a film formation space;
a sputtering cathode including
a target disposed in the vacuum chamber and having a sputtering surface, and
a plurality of magnet units located on a side of the target opposite to the sputtering surface;
a substrate support part disposed to face the target in the vacuum chamber and configured to support a substrate;
a plasma generation power supply configured to supply electric power to the sputtering cathode and to generate plasma in the vacuum chamber;
a gas-atmosphere setting part configured to set a gas atmosphere in the film formation space by supplying gas into the vacuum chamber and discharging the gas from the vacuum chamber; and
a magnetic-field generation power supply configured to supply electric power to the plurality of magnet units and to generate a magnetic field in each of the plurality of magnet units, wherein
the plurality of magnet units are disposed in the film formation space facing the sputtering surface so as to generate a leakage magnetic field obtained by superimposing a plurality of magnetic fields generated by the plurality of magnet units, and
the plurality of magnet units are configured to change the leakage magnetic field, in a direction parallel to a center axis passing through a center of the sputtering surface and extending in a thickness direction of the target, in a radial direction with respect to the center of the sputtering surface, and in a circumferential direction of the sputtering surface around the center axis.

2. The plasma processing apparatus according to claim 1, wherein
each of the plurality of magnet units is disposed to generate the magnetic field in the direction parallel to the center axis, and
two magnet units adjacent to each other out of the plurality of magnet units are disposed to be separated in the radial direction.

3. The plasma processing apparatus according to claim 2, wherein
two magnet units adjacent to each other out of the plurality of magnet units are disposed to be separated in the circumferential direction.

4. The plasma processing apparatus according to claim 3, wherein
each of the plurality of magnet units has a configuration of one of: a permanent magnet; an electromagnet; a combination of a plurality of permanent magnets; a combination of a plurality of electromagnets; and a combination of a permanent magnet and an electromagnet.

5. The plasma processing apparatus according to claim 4, wherein
at least one of the plurality of magnet units includes a plurality of magnets, and
the plurality of magnets generates the magnetic fields in the same direction.

6. The plasma processing apparatus according to claim 4, wherein
at least one of the plurality of magnet units includes an electromagnet,
the electromagnet includes at least a first electromagnet and a second electromagnet,
the first electromagnet includes a first magnetic core and a first coil part wound around the first magnetic core,
the second electromagnet includes a second magnetic core and a second coil part wound around the second magnetic core,
the first electromagnet and the second electromagnet are arranged in the radial direction or the circumferential direction, and
the first electromagnet and the second electromagnet generate the magnetic field in the same direction.

7. A The plasma processing apparatus according to claim 4, wherein
at least one of the plurality of magnet units includes an electromagnet,
the electromagnet includes at least a first electromagnet and a second electromagnet,
the first electromagnet includes a first magnetic core and a first coil part wound around the first magnetic core,
the second electromagnet includes a second magnetic core and a second coil part wound around the second magnetic core,
the first electromagnet and the second electromagnet are arranged in the direction parallel to the center axis, and
the first electromagnet and the second electromagnet generate the magnetic field in the same direction.

8. The plasma processing apparatus according to claim 4, wherein
at least one of the plurality of magnet units includes the electromagnet,
the electromagnet includes a magnetic core, a first coil part wound around the magnetic core, and a second coil part wound around the magnetic core,
the first coil part and the second coil part are arranged in the direction parallel to the center axis, and
the first coil part and the second coil part generate the magnetic field in the same direction.

9. The plasma processing apparatus according to claim 1, wherein
the plurality of magnet units generate a rotating magnetic field rotating with respect to the target or an oscillating magnetic field oscillating with respect to the target.

10. The plasma processing apparatus according to claim 1, further comprising a cooling mechanism configured to cool the plurality of magnet units.
